(19) United States
(12) Patent Application Publication
(10) Pub. No.: US 2026/0018511 A1
(43) Pub. Date: Jan. 15, 2026

(54) SEMICONDUCTOR DEVICE, METHOD OF MANUFACTURING SEMICONDUCTOR DEVICE, AND ELECTRONIC DEVICE

(71) Applicant: Fujitsu Limited, Kawasaki-shi (JP)

(72) Inventors: Yuichi MINOURA, Machida (JP); Atsushi YAMADA, Hiratsuka (JP)

(73) Assignee: Fujitsu Limited, Kawasaki-shi (JP)

(21) Appl. No.: 19/259,328

(22) Filed: Jul. 3, 2025

(30) Foreign Application Priority Data
Jul. 9, 2024 (JP) 2024-109998

(51) Int. Cl. H01L 23/522; H01L 23/528; H10D 30/01; H10D 30/47; H10D 62/10

(52) U.S. Cl. CPC H01L 23/5226; H01L 23/5283; H10D 30/015; H10D 30/475; H10D 62/102; H10D 62/124

(57) ABSTRACT

A semiconductor device includes a substrate, a semiconductor layer, a conductor layer, and wiring. The semiconductor layer is provided on a surface side of the substrate and includes a first portion and a second portion with a larger surface area than the first portion. The conductor layer is provided on an opposite side of the second portion to the substrate. The wiring passes through the substrate and is connected to the conductor layer.

### CROSS-REFERENCE TO RELATED APPLICATION

This application is based upon and claims the benefit of priority of the prior Japanese Patent Application No. 2024-109998, filed on Jul. 9, 2024, the entire contents of which are incorporated herein by reference.

### FIELD

The embodiments discussed herein relate to a semiconductor device, a method of manufacturing a semiconductor device, and an electronic device.

### BACKGROUND

There is a known technology where a metal film containing nickel (Ni) or aluminum (Al) is formed on a nitride semiconductor layer-side of a substrate product, which includes a substrate and a nitride semiconductor layer formed on the substrate, a via hole that reaches the metal film from the substrate side of the substrate product is formed by etching, and a conductive film is formed inside the via hole (see, for example, Japanese Laid-open Patent Publication No. 2020-17647).

### SUMMARY

In one aspect, there is provided a semiconductor device including: a substrate; a semiconductor layer that is provided on a first surface side of the substrate and includes a first portion and a second portion, the second portion having a larger surface area than the first portion; a conductor layer provided on an opposite side of the second portion to the substrate; and wiring that passes through the substrate and is connected to the conductor layer.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIGS. 1A to 1C are diagrams useful in describing one example of a wiring forming method for a semiconductor device;

FIG. 2 is a diagram useful in describing a first example configuration of a semiconductor device according to a first embodiment;

FIGS. 3A to 3C are diagrams useful in describing (a first part of) one example method of manufacturing the semiconductor device according to the first embodiment;

FIGS. 4A to 4C are diagrams useful in describing (a second part of) one example method of manufacturing the semiconductor device according to the first embodiment;

FIG. 5 is a diagram useful in describing a second example configuration of the semiconductor device according to the first embodiment;

FIGS. 6A to 6C are diagrams useful in describing a third example configuration of the semiconductor device according to the first embodiment;

FIGS. 7A to 7C are diagrams useful in describing a fourth example configuration of the semiconductor device according to the first embodiment;

FIG. 8 depicts one example of a semiconductor device according to a second embodiment;

FIGS. 9A to 9C are diagrams useful in describing (a first part of) one example method of manufacturing the semiconductor device according to the second embodiment;

FIGS. 10A to 10C are diagrams useful in describing (a second part of) one example method of manufacturing the semiconductor device according to the second embodiment;

FIGS. 11A to 11C are diagrams useful in describing (a third part of) one example method of manufacturing the semiconductor device according to the second embodiment;

FIGS. 12A and 12B are diagrams useful in describing (a fourth part of) one example method of manufacturing the semiconductor device according to the second embodiment;

FIG. 13 is a diagram useful in describing one example of a semiconductor device according to a third embodiment;

FIGS. 14A to 14C are diagrams useful in describing (a first part of) an example method of manufacturing the semiconductor device according to the third embodiment;

FIGS. 15A and 15B diagrams useful in describing (a second part of) an example method of manufacturing the semiconductor device according to the third embodiment;

FIG. 16 is a diagram useful in describing one example of a semiconductor device according to a fourth embodiment;

FIGS. 17A and 17B are diagrams useful in describing an example method of manufacturing the semiconductor device according to the fourth embodiment;

FIG. 18 is a diagram useful in describing one example of a semiconductor package according to a fifth embodiment;

FIG. 19 is a diagram useful in describing one example of a power factor correction circuit according to a sixth embodiment;

FIG. 20 is a diagram useful in describing one example of a power supply device according to a seventh embodiment; and

FIG. 21 is a diagram useful in describing one example of an amplifier according to an eighth embodiment.

### DESCRIPTION OF EMBODIMENTS

For a semiconductor device where a conductor layer is provided on a semiconductor layer provided on a substrate and wiring is provided to pass through the substrate and connect to the conductor layer, insufficient adhesion between the semiconductor layer and the conductor layer risks peeling of the conductor layer from the semiconductor layer and poor conduction between the conductor layer and the wiring. Peeling of the conductor layer and poor conduction between the conductor layer and the wiring may cause a drop in quality and in the performance of the semiconductor device.

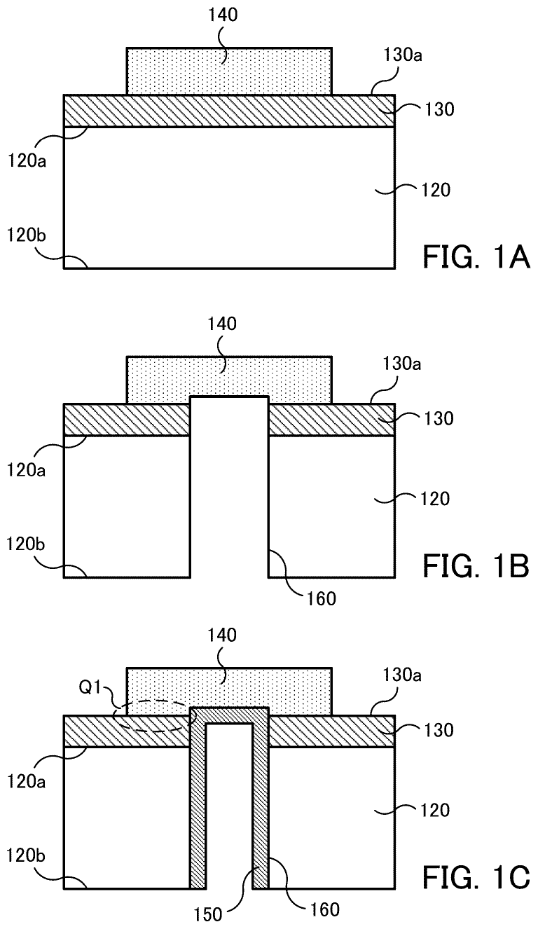

FIGS. 1A to 1C are diagrams useful in describing one example of a wiring forming method for a semiconductor device. FIG. 1A is a schematic cross-sectional view of a principal part of one example of a conductor layer forming process. FIG. 1B is a schematic cross-sectional view of a principal part of one example of a via hole forming process. FIG. 1C is a schematic cross-sectional view of a principal part of one example of a wiring forming process.

As one example, FIG. 1A depicts a structure including a substrate 120 and a semiconductor layer 130 that is provided on a first surface 120a-side of the substrate 120. Various materials may be used for the substrate 120. As examples, silicon carbide (SiC) and silicon (Si) may be used for the substrate 120. Various semiconductor materials may be used for the semiconductor layer 130. As examples, a semiconductor or a compound semiconductor may be used for the semiconductor layer 130. As depicted in FIG. 1A, the conductor layer 140 is provided on a first surface 130a-side of the semiconductor layer 130. Various conductor materials may be used for the conductor layer 140. As examples, a metal such as Ni or Almay be used for the conductor layer 140.

In the structure depicted in FIG. 1A, a via hole 160 is formed so as to pass through the substrate 120 and the semiconductor layer 130 and reach the conductor layer 140 as depicted in FIG. 1B. The via hole 160 is formed by etching the substrate 120 and the semiconductor layer 130 from a second surface 120b-side of the substrate 120. The conductor layer 140 functions as an etch stop layer for this etching. A material that is resistant to the etching performed to form the via hole 160 is used as the conductor layer 140.

After the via hole 160 has been formed, wiring 150 is formed in the via hole 160 as depicted in FIG. 1C. The wiring 150 is provided to cover an inner surface of the via hole 160. The wiring 150 is connected to the conductor layer 140. In addition to functioning as an etch stop layer, the conductor layer 140 functions as a connecting conductor that is connected to the wiring 150. A metal such as gold (Au) is used for the wiring 150. As one example, the wiring 150 is formed on the inner surface of the via hole 160 by plating. Note that the wiring 150 may be formed on the surface 120b-side of the substrate 120 as well as on the inner surface of the via hole 160.

In this semiconductor device, by using a method like that depicted in FIGS. 1A to 1C for example, the conductor layer 140 provided on the surface 120a-side of the substrate 120 is electrically connected to the surface 120b-side of the substrate 120 by the wiring 150 that passes through the semiconductor layer 130 and the substrate 120.

With the structure depicted in FIG. 1C that has been formed using the method described above, peeling of the conductor layer 140 from the semiconductor layer 130 may occur at a boundary, such as a portion marked “Q1” in FIG. 1C, between the conductor layer 140 and the semiconductor layer 130.

As one example, when metals are used for the conductor layer 140 and the wiring 150, relatively high stress may be generated in the metals due to heating performed during manufacturing of the semiconductor device, heat generated during operation, or the like. The conductor layer 140 and the wiring 150 may expand due to the generation of such stress. In addition, adhesion between the conductor layer 140 and the semiconductor layer 130 which use different types of material, such as a conductor and a semiconductor, is likely to be relatively low compared to adhesion between materials of the same type.

When the adhesion between the conductor layer 140 and the semiconductor layer 130 is insufficient, the connection between the layers may be incapable of withstanding the stress or expansion that occurs in the conductor layer 140 and the wiring 150, resulting in the conductor layer 140 peeling off the semiconductor layer 130. Peeling of the conductor layer 140 from the semiconductor layer 130 may cause poor conduction between the conductor layer 140 and the wiring 150, such as electrical disconnection of the wiring 150 connected to the conductor layer 140. Such peeling of the conductor layer 140 and poor conduction between the conductor layer 140 and the wiring 150 may cause a drop in quality and performance of a semiconductor device.

In response to the above problem, a high-quality, high-performance semiconductor device is realized by using the configurations described in the following embodiments.

### First Embodiment

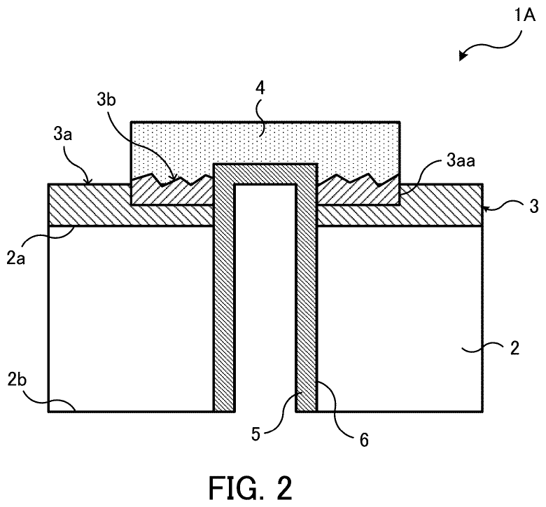

FIG. 2 is a diagram useful in describing a first example configuration of a semiconductor device according to a first embodiment. FIG. 2 is a schematic cross-sectional view of a principal part of one example of a semiconductor device.

A semiconductor device 1A depicted in FIG. 2 includes a substrate 2, a semiconductor layer 3, a conductor layer 4, and wiring 5. The semiconductor layer 3, which includes a first portion 3a and a second portion 3b, is provided on a first surface 2a-side of the substrate 2. The conductor layer 4 is provided on an opposite side of the semiconductor layer 3 to the substrate 2-side. The wiring 5 passes through the substrate 2 and the semiconductor layer 3 and is connected to the conductor layer 4. In the semiconductor device 1A, various transistor elements are formed using the semiconductor layer 3 or the semiconductor layer 3 in combination with the substrate 2. As one example, the semiconductor layer 3 alone or in combination with the substrate 2 may be used to form a high electron mobility transistor (HEMT). Alternatively, the semiconductor layer 3 alone or in combination with the substrate 2 may be used to form a metal insulator semiconductor field effect transistor (MISFET) or the like. For ease of explanation, the description here focuses on a region of the semiconductor device 1A where the wiring 5 is provided and transistor elements are omitted from the drawings.

Various materials may be used for the substrate 2. As one example, SiC is used for the substrate 2. As other examples, a material such as Si, aluminum nitride (AlN), gallium nitride (GaN), or sapphire may be used for the substrate 2. The substrate 2 may be constructed of a single layer of one type of material, or may have a multilayer structure composed of one or two or more types of material.

The semiconductor layer 3 is provided on the first surface 2a-side of the substrate 2. Various semiconductor materials may be used for the semiconductor layer 3. As examples, a semiconductor or a compound semiconductor is used for the semiconductor layer 3. For example, a nitride semiconductor, such as GaN or aluminum gallium nitride (AlGaN) is used for the semiconductor layer 3.

The semiconductor layer includes the first portion 3a and the second portion 3b that has a larger surface area than the first portion 3a. The second portion 3b may have undulations in its surface. The second portion 3b may have larger undulations than the surface of the first portion 3a, or a larger number of undulations. The second portion 3b may have a higher surface roughness than the surface roughness of the first portion 3a. As one example, the second portion 3b has a larger surface area than the first portion 3a due to its surface being provided with undulations of a different size or number from the surface of the first portion 3a and/or a different surface roughness.

As one example, the second portion 3b is provided in a recess 3aa formed in the semiconductor layer 3 or in the first portion 3a of the semiconductor layer 3. Parts of the semiconductor layer 3 aside from the second portion 3b, that is, parts to the side of the second portion 3b or parts to the side and below the second portion 3b may be considered as forming the “first portion 3a”. The “surface” of the first portion 3a referred to here includes a surface of the first portion 3a on the opposite side to the substrate 2-side (this may include an inner surface of the recess 3aa when the recess 3aa is formed). The “surface” of the second portion 3b referred to here includes a surface of the second portion 3b on the opposite side to the substrate 2-side. This surface of the second portion 3b has a larger surface area than the surface of the first portion 3a.

The first portion 3a and the second portion 3b of the semiconductor layer 3 may use the same semiconductor material or may use different semiconductor materials. An n-type semiconductor doped with an n-type impurity may be used for the second portion 3b. The first portion 3a may be constructed of a single layer of one type of semiconductor material, or may have a multilayer structure of one type or two or more types of semiconductor material. The second portion 3b may be constructed of a single layer of one type of semiconductor material, or may have a multilayer structure of one type or two or more types of semiconductor material.

The conductor layer 4 is provided on the opposite side of the second portion 3b of the semiconductor layer 3 to the substrate 2-side. As one example, the conductor layer 4 is provided so as to contact the surface of the second portion 3b, that is, the surface on the opposite side to the substrate 2-side. Various conductor materials may be used for the conductor layer 4, for example, metal. As one example, Ni is used for the conductor layer 4. In place of Ni or together with Ni, another metal such as Au or Al may be used for the conductor layer 4. The conductor layer 4 may be constructed of a single layer of one type of conductor material, or may have a multilayer structure of one type or two or more types of conductor material.

The wiring 5 passes through the substrate 2 and the semiconductor layer 3 and is connected to the conductor layer 4. The wiring 5 is formed in a via hole 6 that passes through the substrate 2 and the semiconductor layer 3 to reach the conductor layer 4. Various conductor materials may be used for the wiring 5, for example, metal. As one example, Au is used for the wiring 5. In place of Au or together with Au, another metal such as titanium (Ti) or copper (Cu) may be used for the wiring 5. The wiring 5 may be constructed of a single layer of one type of conductor material, or may have a multilayer structure of one or two or more types of conductor material. Note that the wiring 5 may be formed on the surface 2b-side of the substrate 2 in addition to the inner surface of the via hole 6.

As one example, the wiring 5 is connected to ground (GND) potential. The conductor layer 4 is connected to an electrode (as one example, a source electrode) of a transistor element (not illustrated), and may function as a connecting conductor that connects the electrode to the wiring 5 which is set at GND potential.

In the semiconductor device 1A with the configuration described above, out of the first portion 3a and the second portion 3b of the semiconductor layer 3, the conductor layer 4 is provided on the second portion 3b whose surface area is larger than the first portion 3a. This means that adhesion of the conductor layer 4 to (the second portion 3b of) the semiconductor layer 3 is improved by an anchoring effect achieved by the second portion 3b having a relatively large surface area. By doing so, the connection between the conductor layer 4 and the semiconductor layer 3 is maintained and resists stress and expansion that occur in the conductor layer 4 and the wiring 5 due to heating performing during manufacturing of the semiconductor device 1A, generation of heat during operation, and the like, so that peeling of the conductor layer 4 from the semiconductor layer 3 is suppressed, which suppresses poor conduction between the conductor layer 4 and the wiring 5, such as disconnection of the wiring 5 connected to the conductor layer 4. The configuration described above realizes a high-quality and high-performance semiconductor device 1A in which peeling of the conductor layer 4 and poor conduction between the conductor layer 4 and the wiring 5 are suppressed. The yield of the semiconductor device 1A is also improved.

Next, a method of manufacturing the semiconductor device 1A with the configuration described above will be described with reference to FIGS. 3A to 3C, FIGS. 4A to 4C, and FIG. 2 which was described above.

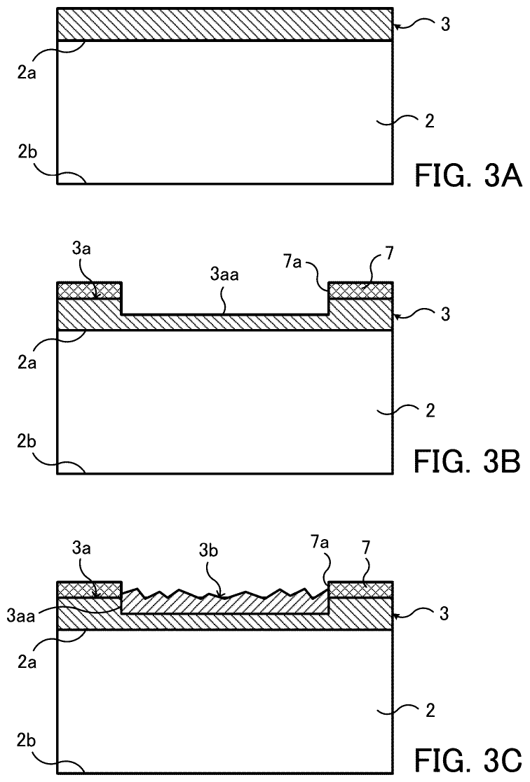

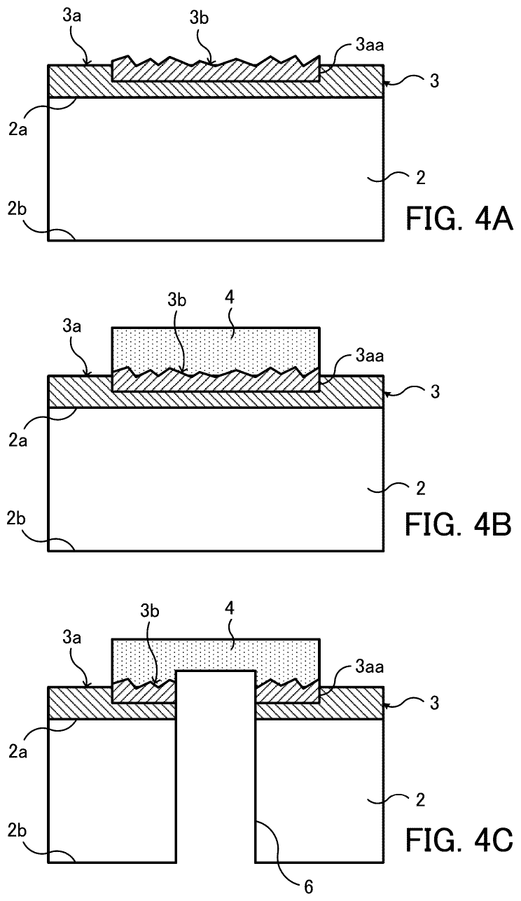

FIGS. 3A to 3C and FIGS. 4A to 4C are diagrams useful in describing one example method of manufacturing a semiconductor device according to the first embodiment. FIGS. 3A to 3C and FIGS. 4A to 4C are schematic cross-sectional views of a principal part of each process during the manufacturing of a semiconductor device.

First, as depicted in FIG. 3A, the semiconductor layer 3 is formed on the first surface 2a-side of the substrate 2. As one example, the semiconductor layer 3 is formed by crystal growth using metal organic chemical vapor deposition (MOCVD) or the like.

After the semiconductor layer 3 has been formed, as depicted in FIG. 3B, a mask 7 is formed with an opening 7a in a region where the second portion 3b is to be formed. A material such as silicon nitride (SiN) is used for the mask 7. After the mask 7 has been formed, a part of the semiconductor layer 3 exposed at the opening 7a is removed by etching to form the recess 3aa. In this example, parts of the semiconductor layer 3 that remain after formation of the recess 3aa, that is, parts outside the recess 3aa or parts outside and inside the recess 3aa form the first portion 3a that has a relatively small surface area.

After formation of the recess 3aa, as depicted in FIG. 3C, the second portion 3b that has a relatively large surface area is formed in the recess 3aa. The second portion 3b is formed by regrowing a predetermined semiconductor using a method such as MOCVD inside the recess 3aa formed in the semiconductor layer 3 which was grown using a method such as MOCVD. The second portion 3b that has been formed in this way by regrowth is also referred to as a “regrowth layer”.

The surface of a second portion 3b formed by regrowth is more likely to have undulations and a larger surface area than the surface of the first portion 3a. It is also possible to form a second portion 3b with a relatively large surface area by adjusting various conditions during regrowth, such as temperature, pressure, and supplied amount of source gas during regrowth. By forming the second portion 3b by regrowth, the second portion 3b that has a larger surface area than the first portion 3a is formed.

By forming the second portion 3b in this way for example, the semiconductor layer 3 including the first portion 3a and the second portion 3b that has a larger surface area than the first portion 3a is formed. After formation of the second portion 3b, as one example, the mask 7 is removed as depicted in FIG. 4A.

Next, as depicted in FIG. 4B, the conductor layer 4 is formed. The conductor layer 4 is formed on the surface of the second portion 3b of the semiconductor layer 3 that has a larger surface area than the first portion 3a. As one example, as the conductor layer 4, a metal containing Ni is formed on the surface of the second portion 3b of the semiconductor layer 3 by vapor deposition or the like. Since the conductor layer 4 is formed on the surface of the second portion 3b with a larger surface area than the first portion 3a, the conductor layer 4 is connected to (the second portion 3b of) the semiconductor layer 3 with a relatively high adhesion force due to the anchoring effect mentioned earlier.

After the conductor layer 4 has been formed, the via hole 6 is formed as depicted in FIG. 4C. The via hole 6 is formed so as to pass through the substrate 2 and the semiconductor layer 3 to reach the conductor layer 4. The via hole 6 is formed by etching the substrate 2 and the semiconductor layer 3 from a second surface 2b-side of the substrate 2. The conductor layer 4 functions as an etch stop layer during this etching. The conductor layer 4 uses a material that is resistant to the etching that forms the via hole 6.

After the via hole 6 has been formed, the wiring 5 is formed inside the via hole 6. By doing so, the state depicted in FIG. 2 described above is obtained. As depicted in FIG. 2, the wiring 5 is provided so as to cover the inner surface of the via hole 6. The wiring 5 is connected to the conductor layer 4 at the bottom of the via hole 6. In addition to functioning as an etch stop layer, the conductor layer 4 functions as a connecting conductor connected to the wiring 5. As one example, as the wiring 5, a metal containing Au is formed on the inner surface of the via hole 6 by a method such as plating. Note that the wiring 5 may be formed on the surface 2b-side of the substrate 2 in addition to the inner surface of the via hole 6.

As one example, the method depicted in FIGS. 3A to 3C and FIGS. 4A to 4C is used to manufacture the semiconductor device 1A (see FIG. 2).

Note that formation of the recess 3aa as depicted in FIG. 3B may be omitted, and a regrowth layer that forms the second portion 3b may be formed in the semiconductor layer 3 that was grown as depicted in FIG. 3A according to the example in FIG. 3C. This reduces the number of processes needed to form the second portion 3b of the semiconductor layer 3.

It is also possible to omit the removal of the mask 7, such as SiN, as depicted in FIG. 4A following the formation of the second portion 3b by regrowth as depicted in FIG. 3C. That is, it is also possible to omit the removal of the mask 7 and perform the formation of the conductor layer 4, the formation of the via hole 6, and the formation of the wiring 5 according to the examples in FIGS. 4B, 4C, and FIG. 2 in a state where the mask 7 remains. The remaining mask 7 may function as a passivation film that protects the surface of the first portion 3a of the semiconductor layer 3.

After the second portion 3b has been regrown as depicted in FIG. 3C, an n-type impurity may be introduced to regrow the n-type second portion 3b. By doing so, the second portion 3b may function as a connecting conductor electrically connected to the conductor layer 4 and the wiring 5.

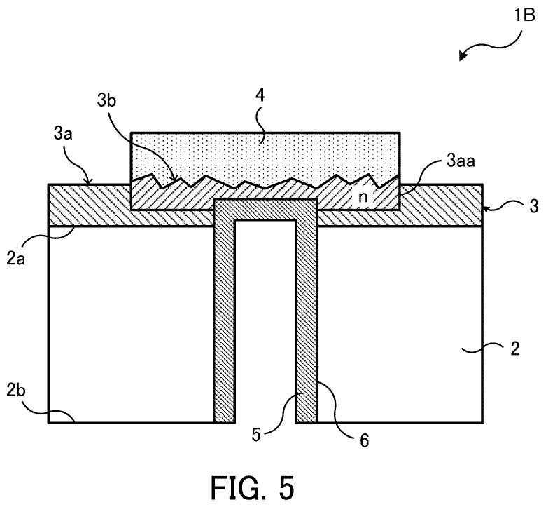

FIG. 5 is a diagram useful in describing a second example configuration of a semiconductor device according to the first embodiment. FIG. 5 is a schematic cross-sectional view of a principal part of one example of a semiconductor device.

In the semiconductor device 1B depicted in FIG. 5, a transistor element such as a HEMT is formed using the semiconductor layer 3 or a combination of the semiconductor layer 3 and the substrate 2. For ease of explanation, the description here focuses on a region of the semiconductor device 1B where the wiring 5 is provided and transistor elements are omitted from the drawings.

The semiconductor device 1B depicted in FIG. 5 has a configuration where the second portion 3b of the semiconductor layer 3 is n-type and the wiring 5 is provided so as to pass through the substrate 2 to reach the second portion 3b. In the semiconductor device 1B, the wiring 5 is provided so as to not pass through the second portion 3b and not to reach the conductor layer 4 provided on the surface of the second portion 3b. In the semiconductor device 1B, the wiring 5 is directly connected to the second portion 3b that is n-type. The wiring 5 is electrically connected to the conductor layer 4 via this n-type second portion 3b. By using this configuration, the semiconductor device 1B differs from the semiconductor device 1A described earlier.

During the manufacturing of the semiconductor device 1B, as one example, after the formation of the semiconductor layer 3 and the recess 3aa as depicted in FIGS. 3A and 3B described above, regrowth of a semiconductor into which an n-type impurity has been introduced is performed in the process in FIG. 3C to form the n-type second portion 3b. The n-type impurity is selected based on the type or the like of semiconductor to be used for the second portion 3b. As examples, Si or germanium (Ge) is used as the n-type impurity. Depending on the type of the semiconductor used as the second portion 3b, phosphorus (P), arsenic (As), or the like may be used as the n-type impurity.

After this, as one example, the conductor layer 4 is formed on the surface of the n-type second portion 3b by the process in FIG. 4A or by an example process in FIG. 4B with the process in FIG. 4A omitted. Next, in the manufacturing of the semiconductor device 1B, the via hole 6 is formed to pass through the substrate 2 to reach the second portion 3b without reaching the conductor layer 4 according to the example process in FIG. 4C. After this, the wiring 5 is formed inside the via hole 6 to obtain the state depicted in FIG. 5. Note that the wiring 5 may be formed on the surface 2b-side of the substrate 2 in addition to the inner surface of the via hole 6.

As one example, this method is used to manufacture a semiconductor device 1B like that depicted in FIG. 5.

In the semiconductor device 1B, the wiring 5 does not pass through the second portion 3b. This means that in the semiconductor device 1B, the contact area between the surface of the second portion 3b and the conductor layer 4 is larger than a configuration where the wiring 5 passes through the second portion 3b. Accordingly, with the semiconductor device 1B, the adhesion of the conductor layer 4 to the semiconductor layer 3 is further increased. By doing so, peeling of the conductor layer 4 from the semiconductor layer 3 is more effectively suppressed, and poor conduction between the conductor layer 4 and the wiring 5, such as disconnection of the wiring 5 connected to the conductor layer 4 is more effectively suppressed.

In addition, in the semiconductor device 1B, since the second portion 3b is n-type, the etching performed when forming the via hole 6 stops at the second portion 3b. This makes it possible to make the etching depth shallower and reduce the etching time compared to a configuration where etching is performed up to the conductor layer 4.

In the semiconductor device 1B, the etching performed when forming the via hole 6 stops at the second portion 3b. This means that the conductor layer 4 does not need a material that is resistant to etching. Accordingly, in the semiconductor device 1B, various conductor materials that are electrically conductive may be used for the conductor layer 4, without the conductor layer 4 being limited to metal such as Ni.

In addition, when the second portion 3b is n-type, when for example a via hole 6 that is supposed to reach the conductor layer 4 is formed by etching but the etching unintentionally stops at the position of the second portion 3b, it will still be possible to electrically connect the wiring 5 and the conductor layer 4. That is, the wiring 5 formed in a via hole 6 that has unintentionally stopped at the position of the second portion 3b and the conductor layer 4 on the surface of the second portion 3b will still be electrically connected via the n-type second portion 3b. Accordingly, when the second portion 3b is n-type, it is possible to ease the restrictions on the etching stop position when forming the via hole 6.

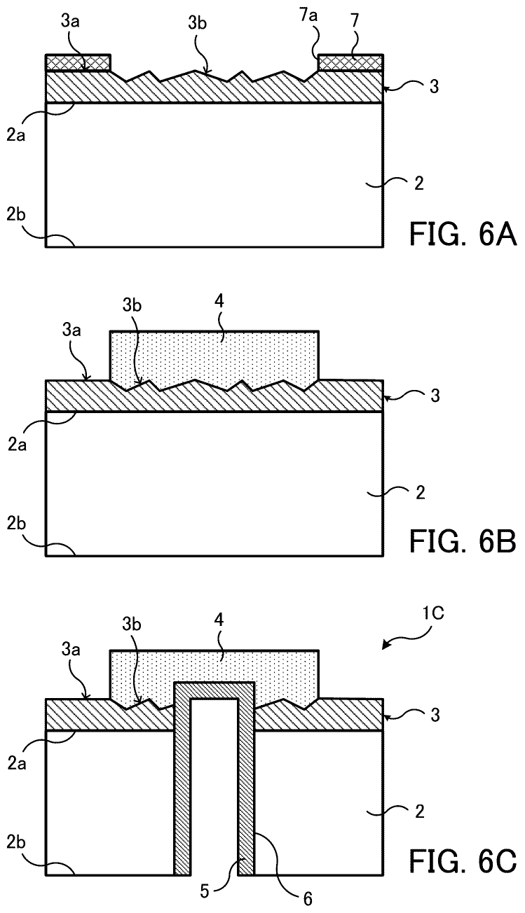

FIGS. 6A to 6C are diagrams useful in describing a third example configuration of a semiconductor device according to the first embodiment. This third example configuration will be described here together with a manufacturing method. FIG. 6A is a schematic cross-sectional view of a principal part of one example of a semiconductor layer forming process. FIG. 6B is a schematic cross-sectional view of a principal part of one example of a conductor layer forming process. FIG. 6C is a schematic cross-sectional view of a principal part of one example of a wiring forming process.

The formation of the second portion 3b of the semiconductor layer 3 with a larger surface area than the first portion is not limited to regrowth of a semiconductor as described above.

As one example, after the semiconductor layer 3 has been formed as depicted in FIG. 3A, as depicted in FIG. 6A, a mask 7 is formed with an opening 7a in a region where the second portion 3b is to be formed, and part of the surface of the semiconductor layer 3 exposed at the opening 7a is processed so as to roughen the surface. This process of roughening a part of the surface of the semiconductor layer 3 may be performed by dry etching, wet etching, a plasma treatment, or the like. The part of the semiconductor layer 3 where such processing is not performed, that is, the part outside the part where the processing is performed, is the first portion 3a.

In this way, a method of processing part of the surface of the semiconductor layer 3 so as to roughen the surface may be used to form the second portion 3b like that depicted in FIG. 6A, that is, the second portion 3b that has a larger surface area than the first portion 3a.

After the second portion 3b has been formed, as depicted in FIG. 6B, the conductor layer 4 is formed on the surface of the second portion 3b that has a larger surface area than the first portion 3a. Next, as depicted in FIG. 6C, a via hole 6 that passes through the substrate 2 and the semiconductor layer 3 to reach the conductor layer 4 is formed, and the wiring 5 is formed inside this via hole 6. Note that the wiring 5 may be formed on the surface 2b-side of the substrate 2 in addition to the inner surface of the via hole 6.

By doing so, the semiconductor device 1C with the configuration depicted in FIG. 6C is manufactured. Note that in the semiconductor device 1C, a transistor element such as a HEMT is formed by the semiconductor layer 3 alone or the semiconductor layer 3 in combination with the substrate 2. For ease of explanation, the description here focuses on a region of the semiconductor device 1C where the wiring 5 is provided and transistor elements are omitted from the drawings.

In the semiconductor device 1C depicted in FIG. 6C, the adhesion of the conductor layer 4 to the is increased by providing the semiconductor layer 3 conductor layer 4 on the second portion 3b formed by processing a part of the surface of the semiconductor layer 3 so as to roughen the surface. By increasing the adhesion of the conductor layer 4, peeling of the conductor layer 4 from the semiconductor layer 3 is suppressed, and poor conduction between the conductor layer 4 and the wiring 5, such as disconnection of the wiring 5 connected to the conductor layer 4, is suppressed.

Note that in the semiconductor device 1C, an n-type impurity may be introduced into the second portion 3b of the semiconductor layer 3 before or after the surface processing described above. For configurations where an n-type impurity is introduced into the second portion 3b, the via hole 6 and the wiring 5 do not need to be formed so as to pass through the substrate 2 and the semiconductor layer 3 to reach the conductor layer 4. That is, a via hole 6 that passes through the substrate 2 to reach the n-type second portion 3b of the semiconductor layer 3 without reaching the conductor layer 4 may be formed, and the wiring 5 may be formed inside this via hole 6. In this case, the wiring 5 is electrically connected to the conductor layer 4 via the n-type second portion 3b.

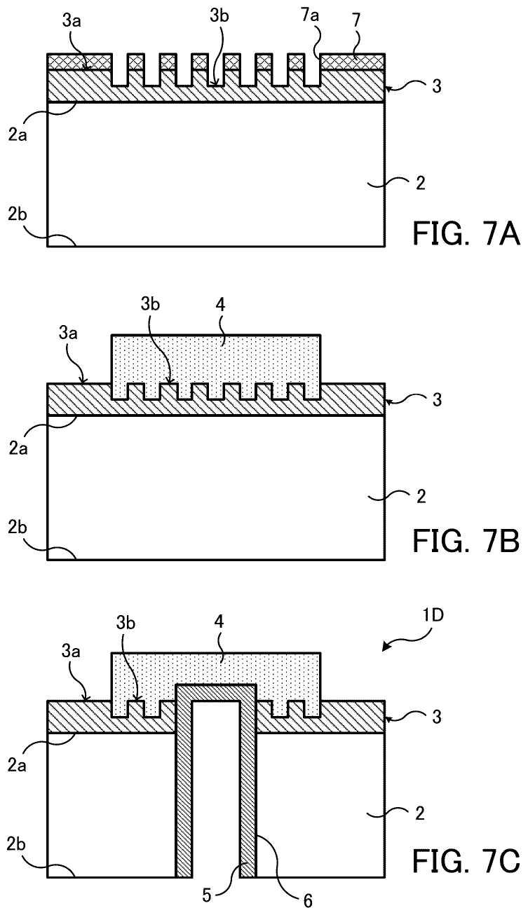

FIGS. 7A to 7C are diagrams useful in describing a fourth example configuration of the semiconductor device according to the first embodiment. Here, the fourth example configuration will be described a together with manufacturing method. FIG. 7A is a schematic cross-sectional view of a principal part of one example of a semiconductor layer forming process. FIG. 7B is a schematic cross-sectional view of a principal part of one example of a conductor layer forming process. FIG. 7C is a schematic cross-sectional view of a principal part of one example of a wiring forming process.

The second portion 3b of the semiconductor layer 3 that has a larger surface area than the first portion 3a may be formed by patterning so as to have a predetermined pattern including undulations.

As one example, after the semiconductor layer 3 has been formed as depicted in FIG. 3A described above, as depicted in FIG. 7A, a mask 7 is formed with openings 7a in regions where concaves are to be formed in the second portion 3b. The openings 7a in the mask 7 may be in various patterns, such as lines, dots, and a lattice. After the mask 7 including the openings 7a in a predetermined pattern has been formed, parts of the surface of the semiconductor layer 3 exposed at the openings 7a are removed by etching so as to form a pattern. Parts of the semiconductor layer 3 where such patterning is not performed, that is, parts outside the part where the patterning is performed form the first portion 3a.

In this way, a method of patterning part of the surface of the semiconductor layer 3 by etching may be used to form a second portion 3b like that depicted in FIG. 7A, that is, a second portion 3b with a larger surface area than the first portion 3a.

After the second portion 3b has been formed, as depicted in FIG. 7B, the conductor layer 4 is formed on the surface of the second portion 3b that has a larger surface area than the first portion 3a. Next, as depicted in FIG. 7C, a via hole 6 that passes through the substrate 2 and the semiconductor layer 3 to reach the conductor layer 4 is formed, and the wiring 5 is formed inside this via hole 6. Note that the wiring 5 may be formed on the surface 2b-side of the substrate 2 in addition to the inner surface of the via hole 6.

By doing so, the semiconductor device 1D with the configuration depicted in FIG. 7C is manufactured. Note that in the semiconductor device 1D, transistor elements such as a HEMT are formed using the semiconductor layer 3 alone or the semiconductor layer 3 in combination with the substrate 2. For ease of explanation, the description here focuses on a region of the semiconductor device 1D where the wiring 5 is provided and transistor elements are omitted from the drawings.

In the semiconductor device 1D, adhesion of the conductor layer 4 to the semiconductor layer 3 is increased by providing the conductor layer 4 on the second portion 3b formed by patterning part of the surface of the semiconductor layer 3. By increasing the adhesion of the conductor layer 4, peeling of the conductor layer 4 from the semiconductor layer 3 is suppressed, and poor conduction between the conductor layer 4 and the wiring 5, such as disconnection of the wiring 5 connected to the conductor layer 4, is suppressed.

Note that for the semiconductor device 1D, an n-type impurity may be introduced into the second portion 3b of the semiconductor layer 3 before or after the patterning described above. For configurations where an n-type impurity is introduced into the second portion 3b, the via hole 6 and the wiring 5 do not need to be formed so as to pass through the substrate 2 and the semiconductor layer 3 to reach the conductor layer 4. That is, a via hole 6 that passes through the substrate 2 to reach the n-type second portion 3b of the semiconductor layer 3 without reaching the conductor layer 4 may be formed, and the wiring 5 may be formed inside this via hole 6. In this case, the wiring 5 is electrically connected to the conductor layer 4 via the n-type second portion 3b.

### Second Embodiment

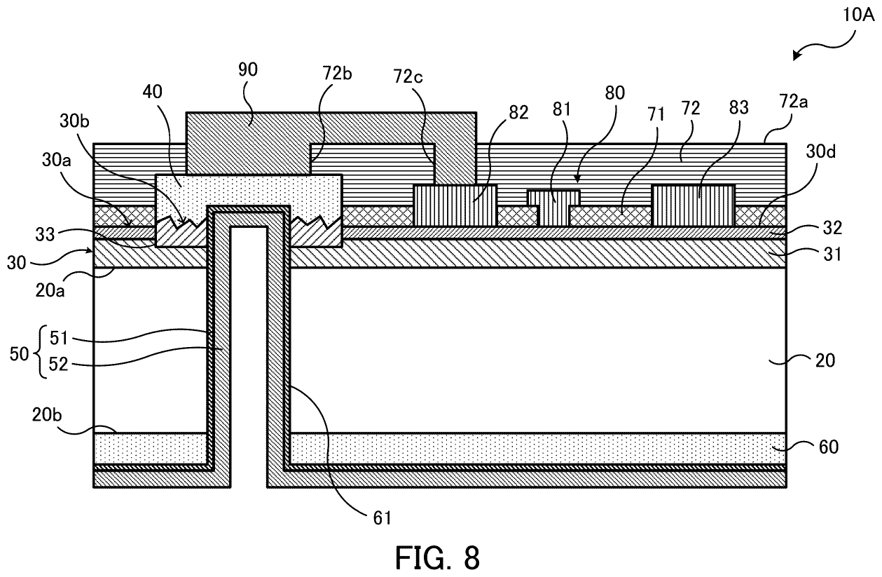

FIG. 8 depicts one example of a semiconductor device according to a second embodiment. FIG. 8 is a schematic cross-sectional view of a principal part of one example of a semiconductor device.

A semiconductor device 10A depicted in FIG. 8 is one example of a HEMT. The semiconductor device 10A includes a substrate 20, a semiconductor layer 30, a conductor layer 40, wiring 50, and a transistor element 80.

As one example, an SiC substrate is used as the substrate 20. As other examples, an Si substrate, an AlN substrate, a GaN substrate, a sapphire substrate, a diamond substrate, or the like may be used as the substrate 20. The substrate 20 may be constructed of one type of substrate in a single layer, or may have a multilayer structure of one or two or more types of substrate.

The semiconductor layer 30 is provided on a first surface 20a-side of the substrate 20. A nitride semiconductor is used for the semiconductor layer 30. The semiconductor layer 30 includes a channel layer 31 and a barrier layer 32. Note that the channel layer 31 is also referred to as an “electron transit layer”. The barrier layer 32 is also referred to as an “electron supply layer”.

A nitride semiconductor such as GaN is used for the channel layer 31. A nitride semiconductor such as AlGaN is used for the barrier layer 32. A nitride semiconductor with a larger band gap than the channel layer 31 is used for the barrier layer 32. In the semiconductor layer 30, due to spontaneous polarization of the barrier layer 32 and piezoelectric polarization that occurs in the barrier layer 32 due to strain caused by the difference in lattice constant from the channel layer 31, a two-dimensional electron gas (2DEG) region is generated in the channel layer 31.

Note that although not illustrated here, a layer of AlN or the like may be provided as an initial layer, a layer of AlGaN or the like may be provided as a buffer layer, and a layer of GaN or the like that has been doped with iron (Fe) may be provided between the substrate 20 and the channel layer 31. Aside from this, a layer of AlN, AlGaN, or the like may be provided as a barrier layer (or “back barrier layer”) for realizing a quantum well (quantum confinement) structure between the substrate 20 and the channel layer 31. A layer of AlN, AlGaN, or the like may be provided as a spacer layer between the channel layer 31 and the barrier layer 32. A layer of GaN or the like may be provided as a cap layer on the barrier layer 32. Aside from the channel layer 31 and the barrier layer 32, the semiconductor layer 30 may include one or more of such initial layer, buffer layer, back barrier layer, spacer layer, cap layer, and the like.

The semiconductor layer 30 includes a first portion 30a and a second portion 30b that has a larger surface area than the first portion 30a. The second portion 30b may have an undulations in its surface. The second portion 30b is provided in a recess 33 formed in the semiconductor layer 30. As one example, the recess 33 is formed to pass through the barrier layer 32 to reach the channel layer 31. A nitride semiconductor such as GaN is used for the second portion 30b. A nitride semiconductor (n-type nitride semiconductor) such as GaN that has been doped with an n-type impurity may be used for the second portion 30b.

The conductor layer 40 is provided on an opposite side to the substrate 20-side of the second portion 30b of the semiconductor layer 30. As one example, the conductor layer 40 is provided so as to contact the surface of the second portion 30b, that is, the surface on the opposite side to the substrate 20-side. As one example, a metal such as Ni or Au is used for the conductor layer 40. The conductor layer 40 may be constructed of a single layer of one type of metal, or may have a multilayer structure of one or two or more types of metal.

A metal layer 60 is provided on a second surface 20b-side of the substrate 20. The wiring 50 passes through the metal layer 60, the substrate 20, and the semiconductor layer 30 to reach the conductor layer 40 and is connected to the conductor layer 40. In the example in FIG. 8, the wiring 50 passes through the metal layer 60, the substrate 20, and the channel layer 31 and the second portion 30b of the semiconductor layer 30, and is connected to the conductor layer 40. The wiring 50 is provided inside a via hole 61 formed so as to pass through the metal layer 60, the substrate 20, and the semiconductor layer 30.

The metal layer 60 is an etching mask used when forming the via hole 61 in the substrate 20 and the semiconductor layer 30 by etching. The metal layer 60 is made of a material that is resistant to the etching that forms the via hole 61. Ni is used for the metal layer 60. In place of Ni or together with Ni, another metal such as Au or Cu may be used for the metal layer 60. The metal layer 60 may be constructed of a single layer of one type of conductor material, or may have a multilayer structure of one or two or more types of conductor material. The conductor layer 40 functions as an etch stop layer when the via hole 61 is formed by etching using the metal layer 60 as an etching mask, and also functions as a connecting conductor that is connected to the wiring 50 formed inside the via hole 61.

The wiring 50 includes a seed layer 51 and a wiring layer 52. As one example, a metal such as Ti or Au is used for the seed layer 51. A metal such as Au is used for the wiring layer 52. The seed layer 51 and the wiring layer 52 may each be constructed of a single layer of one type of metal, or may have a multilayer structure of one or two or more types of metal.

The transistor element 80 includes a gate electrode 81, a source electrode 82, and a drain electrode 83 provided on a surface 30d-side of the semiconductor layer 30 that is opposite the substrate 20-side. The gate electrode 81 is provided between the source electrode 82 and the drain electrode 83. The gate electrode 81 may be disposed closer to the source electrode 82 than the drain electrode 83, that is, an asymmetrical arrangement may be used, to increase the breakdown voltage.

A metal such as Ni or Au is used for the gate electrode 81. The gate electrode 81 is provided to function as a Schottky electrode, for example. Note that although not depicted, the gate electrode 81 may be provided on the surface 30d-side of the semiconductor layer 30 via a gate insulating film to form an MIS gate structure. As the gate insulating film, SiN, silicon oxide (SiO), aluminum oxide (AlO), or the like is used.

A metal such as Ti or Al is used for the source electrode 82 and the drain electrode 83. The source electrode 82 and the drain electrode 83 are provided so as to function as ohmic electrodes. Note that although not depicted, the source electrode 82 and the drain electrode 83 may be provided in recesses formed in the surface 30d-side of the semiconductor layer 30. By doing so, it is possible to reduce the distance between the source electrode 82 and drain electrode 83 and the 2DEG region generated in the channel layer 31, which reduces the ohmic resistance. The source electrode 82 and the drain electrode 83 may be provided on a contact layer of an n-type nitride semiconductor that has been regrown in a recess formed in the surface 30d-side of the semiconductor layer 30.

During operation of the semiconductor device 10A, a voltage that is relatively high compared to the potential of the source electrode 82 is applied to the drain electrode 83 and a predetermined voltage is applied to the gate electrode 81. The electric field effect produced by the voltage applied to the gate electrode 81 controls the amount of charge passing through the 2DEG region that is below the gate electrode 81 and between the source electrode 82 and the drain electrode 83 and thereby controls the drain current that is the output.

A passivation film 71 is provided on the surface 30d-side of the semiconductor layer 30 on which the conductor layer 40 and the gate electrode 81, the source electrode 82, and the drain electrode 83 of the transistor element 80 are provided. An insulating film 72 is provided so as to be laminated on the passivation film 71. An insulating material such as SiN is used for the passivation film 71 and the insulating film 72.

The insulating film 72 is provided with an opening 72b and an opening 72c that communicate with the conductor layer 40 and the source electrode 82, respectively, from a surface 72a of the insulating film 72. Connection wiring 90 that uses a metal such as Ti or Au is provided on the surface 72a and inside the opening 72b and the opening 72c. The conductor layer 40 and the source electrode 82 are connected by this connection wiring 90. Note that the source electrode 82 connected to the conductor layer 40 may also be referred to simply as the “electrode”.

In this way, the source electrode 82 of the transistor element 80 is connected to the conductor layer 40 via the connection wiring 90. The conductor layer 40 is connected to the wiring 50. The wiring 50 passes through the semiconductor layer 30 and the substrate 20 and extends to the surface 20b-side of the substrate 20. The wiring 50 is connected to GND potential, for example. Accordingly, in the semiconductor device 10A, the source electrode 82 is connected to GND via the connection wiring 90, the conductor layer 40, and the wiring 50.

By using this configuration in the semiconductor device 10A, the source inductance is reduced compared with a configuration where the source electrode 82 is connected to GND by a wire or the like on the side where the source electrode 82 is provided. In other words, to reduce the source inductance, the semiconductor device 10A uses a configuration where the source electrode 82 is electrically connected to the surface 20b side of the substrate 20 via the connection wiring 90, the conductor layer 40, and the wiring 50 and connected from there to GND.

In the semiconductor device 10A, the conductor layer 40, which is the etch stop layer when forming the via hole 61 and is also part of a connecting conductor that connects the source electrode 82 to GND, is provided on the second portion 30b, which has a larger surface area than the first portion 30a, of the semiconductor layer 30. Accordingly, adhesion of the conductor layer 40 to (the second portion 30b of) the semiconductor layer 30 is increased by the anchoring effect achieved by the second portion 30b having a relatively large surface area. By doing so, the connection between the conductor layer 40 and the semiconductor layer 30 is maintained and resists stress or expansion that occur in the conductor layer 40 and the wiring 50 due to heating during manufacturing of the semiconductor device 10A, generation of heat during operation, and the like, so that peeling of the conductor layer 40 from the semiconductor layer 30 is suppressed. Since peeling of the conductor layer 40 from the semiconductor layer 30 is suppressed, poor conduction between the conductor layer 40 and the wiring 50, such as disconnection of the wiring 50 connected to the conductor layer 40, is suppressed. The configuration described above realizes a high-quality and high-performance semiconductor device 10A, that is, a HEMT, in which peeling of the conductor layer 40 and poor conduction between the conductor layer 40 and the wiring 50 are suppressed. The yield of the semiconductor device 10A is also improved.

Next, a method of manufacturing the semiconductor device 10A with the configuration described above will be described.

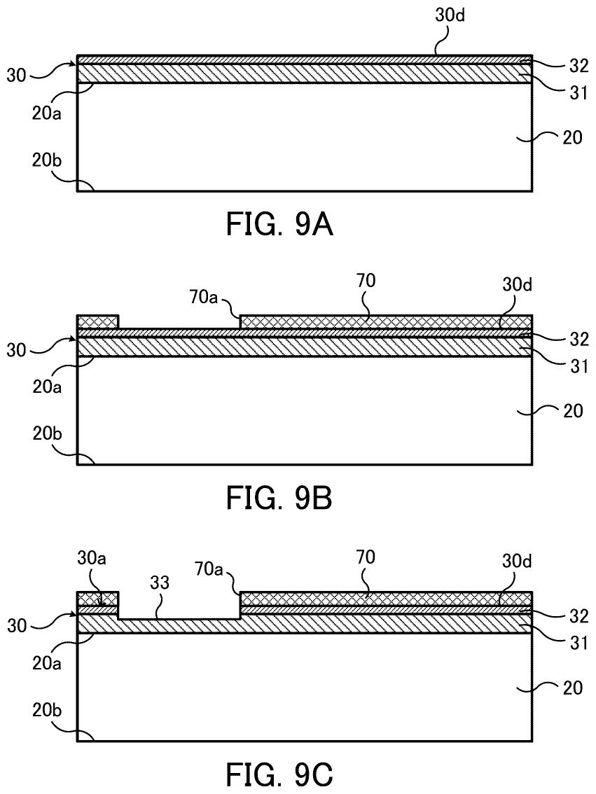

FIGS. 9A to 12B are diagrams useful in describing one example method of manufacturing a semiconductor device according to the second embodiment. FIGS. 9A to 9C, FIGS. 10A to 10C, FIGS. 11A to 11C, and FIGS. 12A and 12B are schematic cross-sectional views of a principal part of each process during the manufacturing of a semiconductor device.

First, as depicted in FIG. 9A, the semiconductor layer 30 is formed on the first surface 20a-side of the substrate 20. The semiconductor layer 30 is formed by crystal growth using MOCVD or the like. As one example, a channel layer 31 of GaN or the like is formed on the surface 20a-side of the substrate 20. A barrier layer 32 of AlGaN or the like is formed on the opposite side of the formed channel layer 31 to the substrate 20-side. Although an example of forming the semiconductor layer 30 that includes two layers, that is, the channel layer 31 and the barrier layer 32, is depicted here, a semiconductor layer 30 that further includes other layers such as an initial layer, a buffer layer, a back barrier layer, a spacer layer, and a cap layer like those described earlier may be formed.

After the semiconductor layer 30 has been formed, inter-element isolation regions (not depicted), which define regions where transistor elements 80 are to be formed, are formed by ion implantation of argon (Ar) or the like.

Next, as depicted in FIG. 9B, a mask 70 is formed with an opening 70a in a region where the second portion 30b of the semiconductor layer 30 is to be formed. As one example, SiN is used for the mask 70. For example, SiN is formed on the surface 30d-side of the semiconductor layer 30 using a plasma CVD or a thermal CVD, and the SiN in the region where the second portion 30b is to be formed is removed by etching using a fluorine-based (F-based) gas. By doing so, the SiN mask 70 that has the opening 70a in the region where the second portion 30b is to be formed is formed.

After formation of the mask 70, as depicted in FIG. 9C, a part of the semiconductor layer 30 exposed at the opening 70a is removed by etching to form the recess 33. As one example, the part of the semiconductor layer 30 exposed in the opening 70a is removed by etching using a chlorine-based (Cl-based) gas. As one example, the recess 33 that has a depth that passes through the barrier layer 32 of the semiconductor layer 30 to reach the channel layer 31 is formed. Parts of the semiconductor layer 30 that remain after the formation of the recess 33, that is, parts outside the recess 33 or outside and inside of the recess 33 form the first portion 30a that has a relatively small surface area.

As described later, the second portion 30b is formed in the recess 33 by regrowth. So long as the second portion 30b may be formed by regrowth, the depth of the recess 33 is not limited to a depth that passes through the barrier layer 32 to reach the channel layer 31. When, according to an example described later, it is possible to form the second portion 30b by regrowth directly on the surface 30d of the semiconductor layer 30 that was formed 5 by crystal growth as depicted in FIG. 9A, the process of forming the recess 33 depicted in FIGS. 9B and 9C may be omitted. For ease of explanation, a configuration where the recess 33 is formed with a depth that reaches the channel layer 31 will be described here as an example.

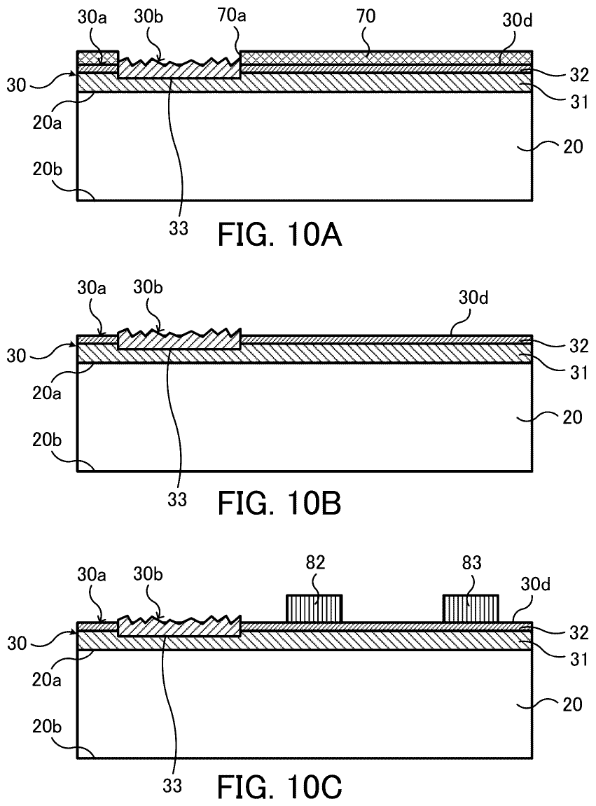

After the recess 33 has been formed, as depicted in FIG. 10A, the second portion 30b with a relatively large surface area is formed in the recess 33. In this example, the second portion 30b is formed by further regrowing a predetermined semiconductor using a method such as MOCVD in the recess 33 formed in the semiconductor layer 30 that was grown using a method such as MOCVD. As one example, as the second portion 30b, a nitride semiconductor, such as GaN, is regrown in the recess 33. An n-type impurity may be introduced into the nitride semiconductor, such as GaN, regrown in the recess 33. That is, a nitride semiconductor such as GaN or a nitride semiconductor (or “n-type nitride semiconductor”) such as GaN containing an n-type impurity is formed in the recess 33 of the semiconductor layer 30 as the second portion 30b that has a relatively large surface area.

The surface of the second portion 30b formed by regrowth is likely to have undulations and a larger surface area than the surface of the first portion 30a. It is also possible to form a second portion 30b with a relatively large surface area by adjusting various conditions during regrowth, such as temperature, pressure, and supplied amount of source gas during regrowth. By forming the second portion 30b by regrowth, the second portion 30b that has a larger surface area than the first portion 30a is formed.

After formation of the second portion 30b by regrowth, as one example, as depicted in FIG. 10B, the mask 70 is removed. As one example, hydrofluoric acid or the like is used to remove the SiN mask 70. Note that the mask 70 may be left as is without being removed and then used as the passivation film 71. For ease of explanation, a case where the mask 70 is removed will be described here as an example.

After the mask 70 is removed, the source electrode 82 and the drain electrode 83 are formed as depicted in FIG. 10C. As one example, Ti and Al are sequentially formed on the surface 30d side of the semiconductor layer 30 by vapor deposition, and a heat treatment is also performed to achieve ohmic contact. By doing so, the source electrode 82 and the drain electrode 83 that function as ohmic electrodes are formed.

Although not depicted in the drawings, before the source electrode 82 and the drain electrode 83 are formed, recesses may be formed in advance in the semiconductor layer 30 in regions where the source electrode 82 and the drain electrode 83 are to be formed, with the source electrode 82 and the drain electrode 83 then being formed in these recesses. This makes it possible to reduce the distance from the source electrode 82 and drain electrode 83 to the 2DEG region generated in the channel layer 31, which reduces the ohmic resistance. Alternatively, contact layers of an n-type nitride semiconductor may be formed in recesses that been formed in advance, and the source electrode 82 and the drain electrode 83 may be formed on these contact layers.

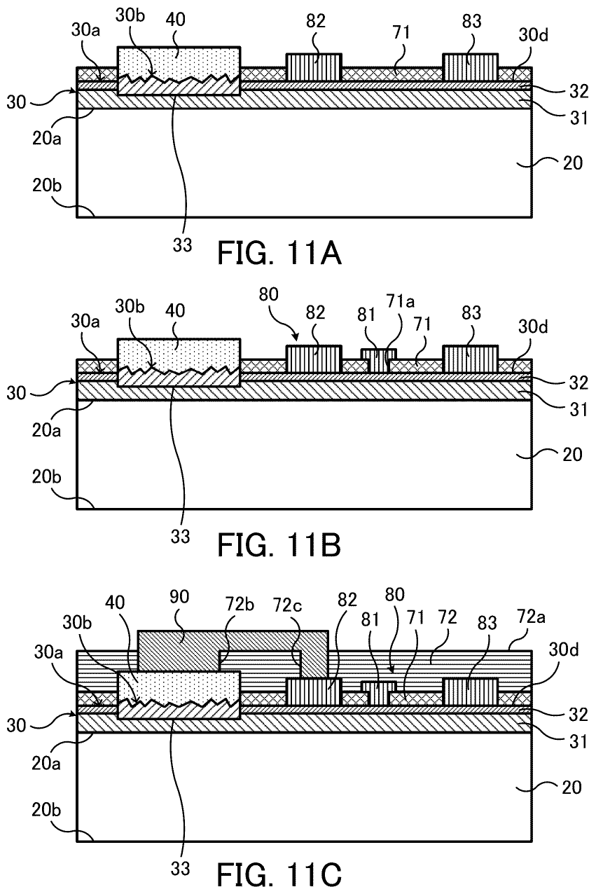

After the source electrode 82 and the drain electrode 83 have been formed, the conductor layer 40 is formed as depicted in FIG. 11A. The conductor layer 40 is formed on the surface of the second portion 30b, which has a relatively large surface area and was is formed in the recess 33 of the semiconductor layer 30 by regrowth. As one example, Ni and Au are sequentially formed by vapor deposition to form the conductor layer 40. In this case, Ni formed on the lower layer-side of the conductor layer 40 is formed as a material that is resistant to the etching performed when forming the via hole 61 as described later. Au formed on the upper layer-side of the conductor layer 40 is formed as a material that suppresses the drop in conductivity with the connection wiring 90, which is formed as described later. Since the conductor layer 40 is formed on the surface of the second portion 30b that has a larger surface area than the first portion 30a, the conductor layer 40 is connected to (the second portion 30b of) the semiconductor layer 30 with relatively high adhesion due to the anchoring effect described earlier.

As one example, after the conductor layer 40 has been formed, the passivation film 71 is formed as depicted in FIG. 11A. As one example, SiN is used for the passivation film 71. As example methods, SiN is formed on the surface 30d-side of the semiconductor layer 30 using plasma CVD or thermal CVD to form the SiN passivation film 71. Note that the passivation film 71 may be formed before the conductor layer 40 is formed.

After the conductor layer 40 and the passivation film 71 have been formed, the gate electrode 81 is formed as depicted in FIG. 11B. As one example, first, part of the passivation film 71 in a region where the gate electrode 81 is to be formed is removed by etching using an F-based gas to form an opening 71a that communicates with the semiconductor layer 30. After this, Ni and Au are sequentially formed in the formed opening 71a by vapor deposition to form the gate electrode 81. By doing so, the transistor element 80 including the gate electrode 81, the source electrode 82, and the drain electrode 83 provided on the surface 30d-side of the semiconductor layer 30 is formed.

Note that when the material used for the conductor layer 40 is the same as the material used for the gate electrode 81, the conductor layer 40 may be formed at the same time as formation of the gate electrode 81. In this case, for example, after the source electrode 82, the drain electrode 83, and the passivation film 71 have been formed, openings are formed in a region where the gate electrode 81 is to be formed and a region where the conductor layer 40 is to be formed. The gate electrode 81 and the conductor layer 40 are then simultaneously formed by forming Ni, Au, and the like by vapor deposition in these formed openings.

After the gate electrode 81 is formed, as depicted in FIG. 11C, the insulating film 72 and the connection wiring 90 are formed. SiN for example is used for the insulating film 72. As one example, SiN is first formed on the entire surface using plasma CVD or thermal CVD so as to form the insulating film 72 that covers the gate electrode 81, the source electrode 82, the drain electrode 83, the conductor layer 40, and the passivation film 71. Next, the opening 72b and the opening 72c that communicate with the conductor layer 40 and the source electrode 82, respectively, are formed from the surface 72a of the formed insulating film 72 by etching using an F-based gas. After this, a metal such as Ti or Au is formed on the surface 72a and in the opening 72b and the opening 72c using plating, sputtering, or both of these methods to form the connection wiring 90. By doing so, the conductor layer 40 and the source electrode 82 are connected by the connection wiring 90.

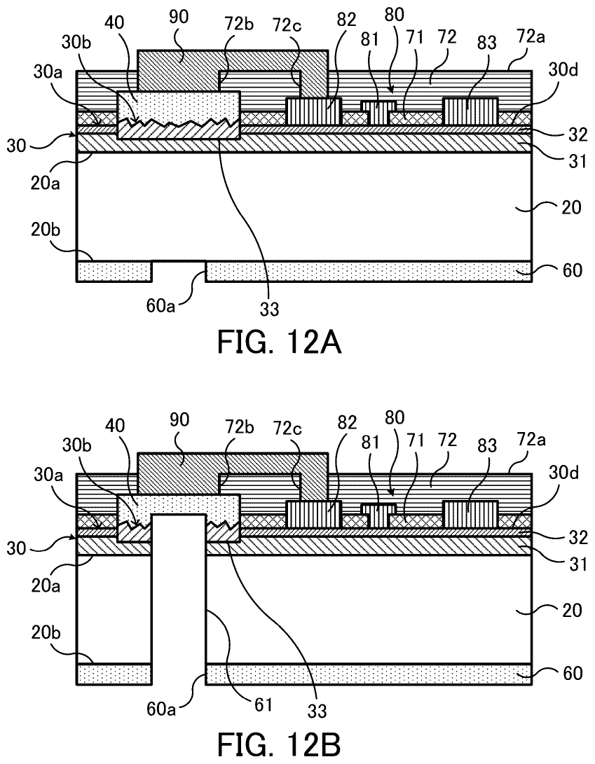

After the insulating film 72 and the connection wiring 90 are formed, as depicted in FIG. 12A, the metal layer 60 that has the opening 60a in a region corresponding to the second portion 30b of the semiconductor layer 30 and the conductor layer 40 on the second portion 30b, that is, the region where the via hole 61 is to be formed, is formed on the surface 20b-side of the substrate 20. The metal layer 60 functions as an etching mask when the via hole 61 is formed as described later. The metal layer 60 is made of a material that is resistant to the etching that forms the via hole 61. As one example, Ni is used for the metal layer 60. When the via hole 61 is formed, the metal layer 60 is exposed to etching for a relatively long time. For this reason, the metal layer 60 is preferably formed with a thickness that is not removed by etching when the via hole 61 is formed, as one example, a thickness of 1 μm or more. As one example, Ni with a predetermined thickness is formed by plating to form the metal layer 60.

After the metal layer 60 is formed, the via hole 61 is formed as depicted in FIG. 12B. That is, the metal layer 60 is used as an etching mask and the substrate 20 and the semiconductor layer 30 exposed at the opening 60a are etched to form the via hole 61 that reaches the conductor layer 40. When an Si-based semiconductor material such as SiC is used for the substrate 20, an F-based gas is used for the etching that forms the via hole 61. As the F-based gas, as one example a mixed gas of sulfur hexafluoride (SF₆) and oxygen (O₂) is used. Note that when forming the via hole 61, a Cl-based gas may be used to etch the semiconductor layer 30 that uses a nitride semiconductor. Etching using a predetermined gas is performed using the metal layer 60 provided with the opening 60a as an etching mask. This etching stops at the position of the conductor layer 40. As a result, the via hole 61 that passes through the substrate 20 and the semiconductor layer 30 to reach the conductor layer 40 is formed.

After the via hole 61 has been formed, the wiring 50 is formed, thereby producing the state depicted in FIG. 8 described earlier. When forming the wiring 50, the seed layer 51 is formed first. As one example, Ti and Au are sequentially formed by sputtering to form the seed layer 51. Next, the wiring layer 52 is formed on the formed seed layer 51. As one example, Au is formed by plating to form the wiring layer 52. By doing so, the wiring 50 including the seed layer 51 and the wiring layer 52 is formed. The wiring 50 is formed so as to be connected to the conductor layer 40 at the bottom of the via hole 61. The wiring 50 may be formed on the metal layer 60 provided on the surface 20b-side of the substrate 20 in addition to the inner surface of the via hole 61.

Through the processes described above, the semiconductor device 10A with the configuration depicted in FIG. 8 described above is manufactured.

In the semiconductor device 10A, the conductor layer 40 is provided on the second portion 30b of the semiconductor layer 30 that has a larger surface area than the first portion 30a. This means that adhesion of the conductor layer 40 to the semiconductor layer 30 is increased by an anchoring effect. By doing so, peeling of the conductor layer 40 from the semiconductor layer 30 during manufacturing or operation of the semiconductor device 10A is suppressed, and poor conduction such as disconnection between the conductor layer 40 and the wiring 50 is suppressed. Accordingly, a high-quality and high-performance semiconductor device 10A, that is, a HEMT, is realized. The yield of the semiconductor device 10A is also improved.

### Third Embodiment

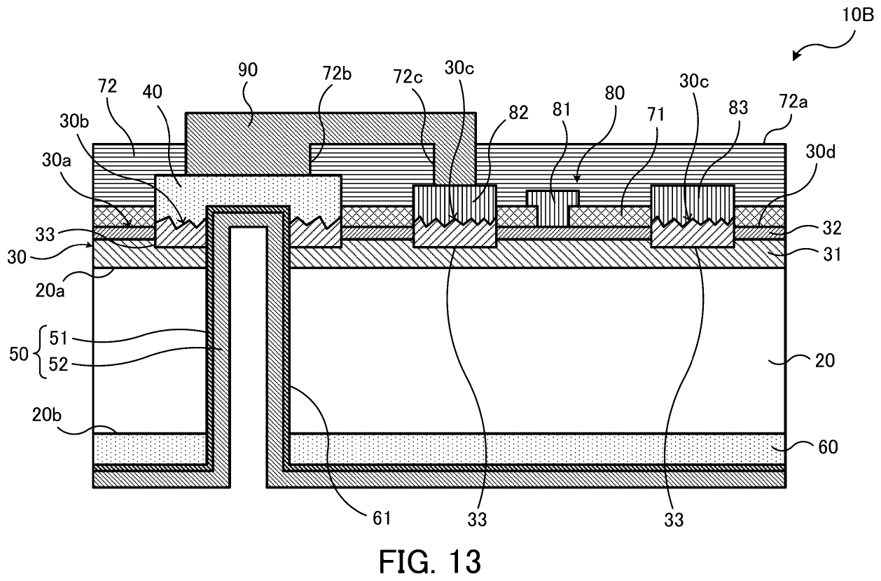

FIG. 13 is a diagram useful in describing one example of a semiconductor device according to a third embodiment. FIG. 13 is a schematic cross-sectional view of a principal part of one example of the semiconductor device.

A semiconductor device 10B depicted in FIG. 13 is one example of a HEMT. The semiconductor device 10B has a configuration where third portions 30c with a larger surface area than the first portion 30a are provided in regions of the semiconductor layer 30 where the source electrode 82 and the drain electrode 83 of the transistor element 80 are provided. Each third portion 30c includes an n-type impurity. By using this configuration, the semiconductor device 10B differs from the semiconductor device 10A described in the second embodiment.

Each third portion 30c of the semiconductor layer 30 may have undulations in its surface. The third portions 30c are provided in recesses 33 formed in the semiconductor layer 30. As one example, the recesses 33 are formed to pass through the barrier layer 32 and reach the channel layer 31. A nitride semiconductor such as GaN is used for the third portions 30c. Alternatively, a nitride semiconductor (n-type nitride semiconductor) such as GaN doped with an n-type impurity is used for the third portions 30c.

The third portions 30c function as contact layers that reduce the contact resistance between the semiconductor layer 30 and the source electrode 82 and drain electrode 83. By providing the source electrode 82 and drain electrode 83 on the third portions 30c that have a relatively large surface area, adhesion of the source electrode 82 and the drain electrode 83 to (the third portions 30c of) the semiconductor layer 30 is increased by the anchoring effect achieved by the third portions 30c. This suppresses peeling of the source electrode 82 and the drain electrode 83 from the semiconductor layer 30.

Also in this semiconductor device 10B, like the semiconductor device 10A described earlier, the conductor layer 40 is provided on the second portion 30b that has a relatively large surface area, so that the adhesion of the conductor layer 40 to (the second portion 30b of) the semiconductor layer 30 is improved by the anchoring effect achieved by the second portion 30b. By doing so, peeling of the conductor layer 40 from the semiconductor layer 30 is suppressed.

Next, a method of manufacturing the semiconductor device 10B with the configuration described above will be described.

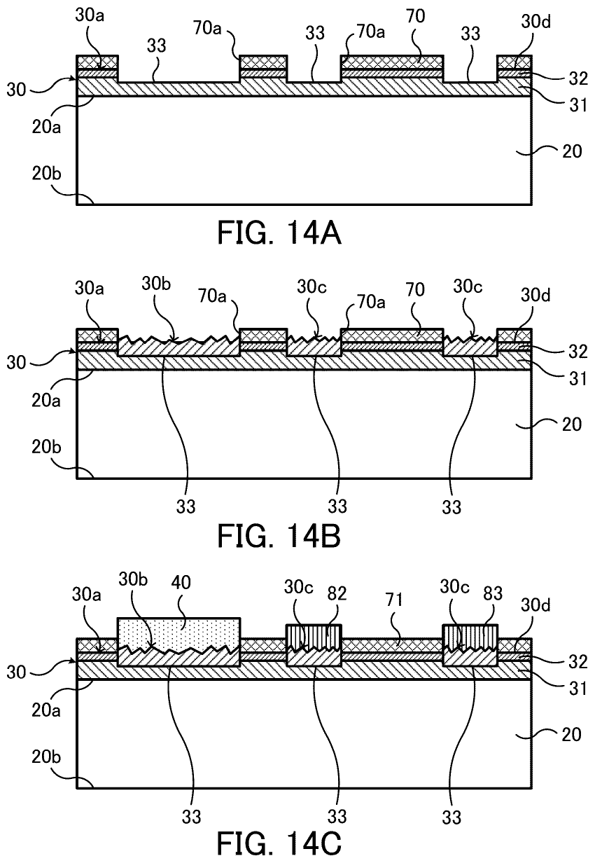

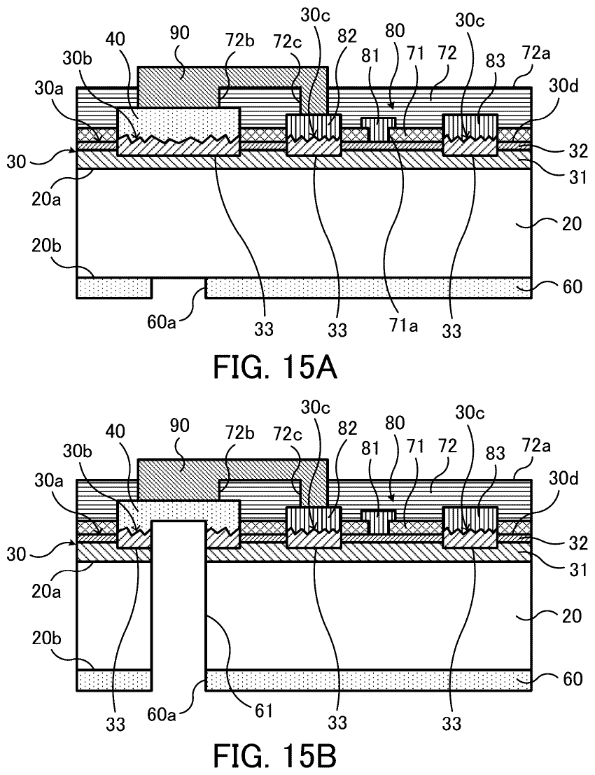

FIGS. 14A to 14C and FIGS. 15A and 15B are diagrams useful in describing an example method of manufacturing the semiconductor device according to the third embodiment. FIGS. 14A to 14C, and FIGS. 15A and 15B are schematic cross-sectional views of principal parts of each process in the manufacturing of the semiconductor device.

In the manufacturing of the semiconductor device 10B, as depicted in FIG. 14A, a mask 70 with openings 70a in regions where the second portion 30b and the third portions 30c of the semiconductor layer 30 are to be formed is formed on the semiconductor layer 30 that was formed on the first surface 20a-side of the substrate 20 by MOCVD or the like.

As one example, a SiC substrate is used as the substrate 20. As one example of the semiconductor layer 30, a layer including a channel layer 31 of GaN or the like and a barrier layer 32 of AlGaN or the like are formed. The semiconductor layer 30 may further include other layers, such as an initial layer, a buffer layer, a back barrier layer, a spacer layer, and a cap layer. SiN is used for the mask 70. The SiN of the mask 70 is formed using plasma CVD or thermal CVD. Part of the formed SiN is removed by etching using an F-based gas to form the mask 70 with the openings 70a in the regions where the second portion 30b and the third portions 30c are to be formed.

After the mask 70 has been formed, as depicted in FIG. 14A, parts of the semiconductor layer 30 exposed at the openings 70a are removed by etching so that the recesses 33 are formed in the regions where the second portion 30b and the third portions 30c of the semiconductor layer 30 are to be formed. The recesses 33 are formed with a depth that passes through the barrier layer 32 to reach the channel layer 31 of the semiconductor layer 30. Parts of the semiconductor layer 30 remaining after the formation of the recesses 33, that is, parts outside the recesses 33 or parts outside and inside the recesses 33 form the first portion 30a that has a relatively small surface area.

After the recesses 33 have been formed, as depicted in FIG. 14B, the second portion 30b and the third portions 30c that have a relatively large surface area are formed in the recesses 33. The second portion 30b and the third portions 30c are formed by further regrowing a predetermined semiconductor using MOCVD or the like inside the recesses 33 formed in the semiconductor layer 30 that was grown using MOCVD or the like. The second portion 30b and the third portions 30c are simultaneously formed by this regrowth. As one example, a nitride semiconductor such as GaN is regrown in the recesses 33 as the second portion 30b and the third portions 30c. An n-type impurity is introduced into the nitride semiconductor, such as GaN, regrown in the recesses 33. That is, a nitride semiconductor such as GaN containing n-type impurities is formed in a recess 33 of the semiconductor layer 30 as the second portion 30b with a relatively large surface area.

Here, in the semiconductor device 10B, the second portion 30b formed by regrowth serves as a base of the conductor layer 40 to be formed as described later. In addition, the third portions 30c formed by regrowth are a base of the source electrode 82 and the drain electrode 83 to be formed as described later, and serve as contact layers. During the manufacturing of the semiconductor device 10B, the second portion 30b that serves as the base of the conductor layer 40 is formed simultaneously with the third portions 30c formed by regrowth as contact layers for the source electrode 82 and the drain electrode 83. Here, it is possible to say that during the manufacturing of the semiconductor device 10B, the second portion 30b that serves as the base of the conductor layer 40 is regrown simultaneously with the regrowth of the third portions 30c that serves as the contact layers of the source electrode 82 and the drain electrode 83.

The surfaces of the second portion 30b and the third portions 30c formed by regrowth are more likely to include undulations and have a larger surface area than the surface of the first portion 30a. It is also possible to form the second portion 30b and the third portions 30c with relatively large surface areas by adjusting the conditions during regrowth, such as temperature, pressure, and supplied amount of source gas during regrowth. By forming the second portion 30b and the third portions 30c by regrowth, the second portion 30b and the third portions 30c that have a larger surface area than the first portion 30a are formed.

After forming the second portion 30b and the third portions 30c by regrowth as depicted in FIG. 14B, the mask 70 may be removed. Alternatively, the mask 70 may be left as is without being removed and used as the passivation film 71. Here, a case where the mask 70 is left, and this remaining mask 70 is used as the passivation film 71 in processes from FIG. 14C onwards will be described as an example.

After the second portion 30b and the third portions 30c have been formed, as depicted in FIG. 14C, the source electrode 82 and the drain electrode 83 are formed. The source electrode 82 and the drain electrode 83 are formed on the surfaces of the third portions 30c that have a relatively large surface area and have been formed in the recesses 33 of the semiconductor layer 30 by regrowth. As one example, Ti and Al are sequentially formed on the surface 30d-side of the semiconductor layer 30 by vapor deposition, and a heat treatment is further performed to achieve ohmic contact. By doing so, the source electrode 82 and the drain electrode 83 that function as ohmic electrodes are formed. Since the source electrode 82 and the drain electrode 83 are formed on the surfaces of the third portions 30c that have a larger surface area than the first portion 30a, the source electrode 82 and the drain electrode 83 are connected to (the third portions 30c of) the semiconductor layer 30 with relatively high adhesion due to an anchoring effect.

In addition, as depicted in FIG. 14C, the conductor layer 40 is formed. The conductor layer 40 is formed on the surface of the second portion 30b that has a relatively large surface area and has been formed in a recess 33 of the semiconductor layer 30 by regrowth. As one example, Ni and Au are sequentially formed by vapor deposition to form the conductor layer 40. In this case, Ni formed on the lower layer-side of the conductor layer 40 is formed as a material that is resistant to the etching that forms the via hole 61 as described later. Au formed on the upper layer-side of the conductor layer 40 is formed as a material that suppresses a drop in conductivity with the connection wiring 90 to be formed as described later. Since the conductor layer 40 is formed on the surface of the second portion 30b that has a larger surface area than the first portion 30a, the conductor layer 40 is connected to (the second portion 30b of) the semiconductor layer 30 with relatively high adhesion due to an anchoring effect.

After the source electrode 82, the drain electrode 83, and the conductor layer 40 have been formed, as depicted in FIG. 15A, the gate electrode 81, the insulating film 72, the connection wiring 90, and the metal layer 60 are formed.

As one example, first, a part of the passivation film 71 in a region where the gate electrode 81 is to be formed is removed by etching using an F-based gas to form the opening 71a. Ni and Au are then sequentially formed in this formed opening 71a by vapor deposition to form the gate electrode 81. Note that when the materials used for the conductor layer 40 are the same as the materials used for the gate electrode 81, the conductor layer 40 may be formed simultaneously with the formation of the gate electrode 81.

After the gate electrode 81 has been formed, the insulating film 72 that uses SiN, for example, is formed on the entire surface by plasma CVD or thermal CVD. Next, the opening 72b and the opening 72c that communicate with the conductor layer 40 and the source electrode 82, respectively, are formed from the surface 72a of the formed insulating film 72 by etching using an F-based gas. After this, a metal such as Ti or Au is formed on the surface 72a and inside the opening 72b and inside the opening 72c using plating, sputtering, or both of these methods to form the connection wiring 90. By doing so, the conductor layer 40 and the source electrode 82 are connected by the connection wiring 90.

In addition, the metal layer 60, which has the opening 60a in a region corresponding to the second portion 30b of the semiconductor layer 30 and the conductor layer 40 on the second portion 30b, that is, the region where the via hole 61 is to be formed, is formed on the surface 20b-side of the substrate 20. The metal layer 60 functions as an etching mask when the via hole 61 is formed as described later. The metal layer 60 is made of a material that is resistant to the etching that forms the via hole 61. As one example, Ni with a predetermined thickness that is not removed due to the etching when the via hole 61 is formed is formed by plating to form the metal layer 60.

After the gate electrode 81, the insulating film 72, the connection wiring 90, and the metal layer 60 have been formed, the via hole 61 is formed as depicted in FIG. 15B. That is, by using the metal layer 60 as an etching mask, the substrate 20 and the semiconductor layer 30 exposed at the opening 60a are etched to form the via hole 61 that reaches the conductor layer 40. When a Si-based semiconductor material such as SiC is used for the substrate 20, an F-based gas is used for the etching that forms the via hole 61. Note that when forming the via hole 61, a Cl-based gas may be used for etching the semiconductor layer 30 that uses a nitride semiconductor. Etching using a predetermined gas is performed using the metal layer 60 provided with the opening 60a as an etching mask. The etching stops at the position of the conductor layer 40. By doing so, the via hole 61 that passes through the substrate 20 and the semiconductor layer 30 to reach the conductor layer 40 is formed.

After the via hole 61 has been formed, the wiring 50 is formed to produce the state depicted in FIG. 13. When forming the wiring 50, as one example, Ti and Au are sequentially formed by sputtering to form the seed layer 51. Next, as one example, Au is formed on the formed seed layer 51 by plating to form the wiring layer 52. By doing so, the wiring 50 including the seed layer 51 and the wiring layer 52 is formed. The wiring 50 is formed so as to be connected to the conductor layer 40 at the bottom of the via hole 61. The wiring 50 may be formed on the metal layer 60 provided on the surface 20b-side of the substrate 20 in addition to the inner surface of the via hole 61.

Through the processes described above, the semiconductor device 10B with the configuration depicted in FIG. 13 described above is manufactured.

In the semiconductor device 10B, the conductor layer 40 is provided on the second portion 30b of the semiconductor layer 30 that has a larger surface area than the first portion 30a. This means that adhesion of the conductor layer 40 to the semiconductor layer 30 is improved by an anchoring effect. By doing so, peeling of the conductor layer 40 from the semiconductor layer 30 during manufacturing or operation of the semiconductor device 10B is suppressed, and poor conduction, such as disconnection, between the conductor layer 40 and the wiring 50 is suppressed. Accordingly, a high-quality and high-performance semiconductor device 10B, that is, a HEMT, is realized. The yield of the semiconductor device 10B is also improved.

During the manufacturing of the semiconductor device 10B, the second portion 30b that serves as the base of the conductor layer 40 is formed by regrowth simultaneously with the third portions 30c that serve as the contact layers of the source electrode 82 and the drain electrode 83. By doing so, a high-quality and high-performance semiconductor device 10B that is equipped with contact layers and also has a conductor layer 40 with high adhesion is manufactured, while suppressing an increase in the number of processes.

Note that in the manufacturing of the semiconductor device 10B, during the process of forming the via hole 61 (FIG. 15B), the via hole 61 may be formed to pass through the metal layer 60 and the substrate 20 to reach the second portion 30b of the semiconductor layer 30 without reaching the conductor layer 40. This is because the second portion 30b is regrown simultaneously with the third portion 30c to be n-type, so that even when a via hole 61 that does not reach the conductor layer 40 has been formed and the wiring 50 has been formed inside, the wiring 50 and the conductor layer 40 will be electrically connected via the n-type second portion 30b.

### Fourth Embodiment

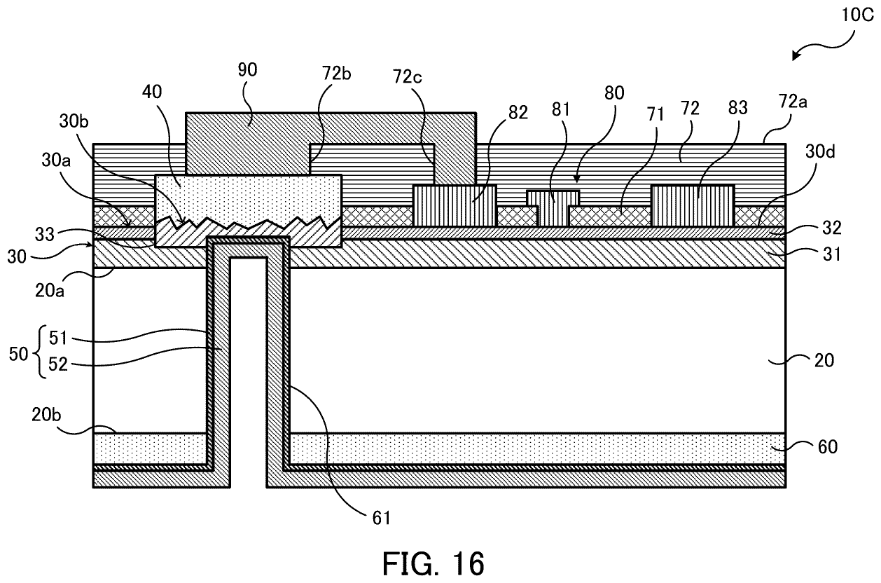

FIG. 16 is a diagram useful in describing one example of a semiconductor device according to a fourth embodiment. FIG. 16 is a schematic cross-sectional view of a principal part of one example of the semiconductor device.

A semiconductor device 10C depicted in FIG. 16 is an example of a HEMT. The semiconductor device 10C has a configuration where the second portion 30b of the semiconductor layer 30 is n-type, and the wiring 50 is provided so as to pass through the substrate 20 and reach the second portion 30b. In the semiconductor device 10C, the wiring 50 is provided so as not to pass through the second portion 30b and not reach the conductor layer 40. In the semiconductor device 10C, the wiring 50 is directly connected to the second portion 30b that is n-type. The wiring 50 is electrically connected to the conductor layer 40 via the second portion 30b that is n-type. By using this configuration, the semiconductor device 10C differs from the semiconductor device 10A described in the second embodiment.

In the semiconductor device 10C, the wiring 50 does not pass through the second portion 30b. This means that in the semiconductor device 10C, the contact area between the second portion 30b and the conductor layer 40 is larger than in a configuration where the wiring 50 passes through the second portion 30b. Accordingly, in the semiconductor device 10C, the adhesion of the conductor layer 40 to (the second portion 30b of) the semiconductor layer 30 is further improved. By doing so, peeling of the conductor layer 40 from the semiconductor layer 30 is more effectively suppressed, and poor conduction between the conductor layer 40 and the wiring 50, such as disconnection of the wiring 50 connected to the conductor layer 40, is more effectively suppressed.

In the semiconductor device 10C, the etching that forms the via hole 61 stops at the second portion 30b. Accordingly, the etching depth is made shallower and the etching time is shortened compared with a configuration where the conductor layer 40 is etched.

In the semiconductor device 10C, the etching for forming the via hole 61 stops at the second portion 30b. This means that a material that is resistant to the etching is not needed for the conductor layer 40. Accordingly, in the semiconductor device 10C, the conductor layer 40 is not limited to a metal, such as Ni, and various conductor materials that conduct electricity may be used.

With the semiconductor device 10C, even when etching that attempts to form a via hole 61 that reaches the conductor layer 40 unintentionally stops at the position of the second portion 30b, the wiring 50 formed in such via hole 61 and the conductor layer 40 will still be electrically connected via the n-type second portion 30b. Accordingly, it is possible to ease the restrictions on the etching stop position when forming the via hole 61.

Next, a method of manufacturing the semiconductor device 10C with the configuration described above will be described.

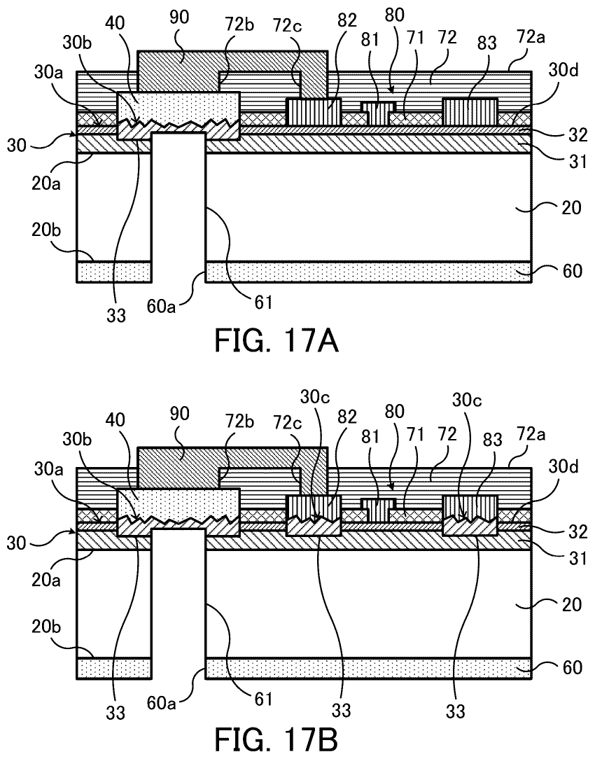

FIGS. 17A and 17B are diagrams useful in describing an example method of manufacturing the semiconductor device according to the fourth embodiment. FIGS. 17A and 17B are schematic cross-sectional views of a principal part of processes in the manufacturing of a semiconductor device.

When manufacturing the semiconductor device 10C, the processes of FIGS. 9A to 9C, FIGS. 10A to 10C, FIGS. 11A to 11C, and FIG. 12A described in the second embodiment may be performed with the same procedure as described earlier.

However, the in manufacturing of the semiconductor device 10C, during the process of forming the second portion 30b by regrowth (see FIG. 10A), the second portion 30b is preferably regrown to be relatively thick. In the manufacturing of the semiconductor device 10C, since the second portion 30b serves as a stop position of the etching when forming the via hole 61, it is preferable for the second portion 30b to be regrown to a relatively large thickness in advance so that the via hole 61 does not pass through the second portion 30b during etching. As one example, the second portion 30b is regrown so as to have a thickness of 1 μm or more. An n-type impurity is introduced into the regrown second portion 30b.

In the manufacturing of the semiconductor device 10C, during the process of forming the conductor layer 40 (see FIG. 11A), the conductor layer 40 may be formed using not only metal such as Ni or Au but also various conductor materials that conduct electricity. This is because the etching that forms the via hole 61 stops at the second portion 30b, which means that a material that is resistant to etching is not needed for the conductor layer 40.

In the manufacturing of the semiconductor device 10C, as one example, the respective processes are performed according to the examples described with reference to FIGS. 9A to 9C, FIGS. 10A to 10C, FIGS. 11A to 11C, and FIG. 12A while taking into account the thickness of the second portion 30b, the introduction of the n-type impurity, and the material of the conductor layer 40.

In the manufacturing of the semiconductor device 10C, after the state depicted in FIG. 12A has been obtained, the via hole 61 that reaches the second portion 30b but does not reach the conductor layer 40 is formed as depicted in FIG. 17A. When an Si-based semiconductor material such as SiC is used for the substrate 20, an F-based gas is used for the etching that forms the via hole 61. Note that when forming the via hole 61, a Cl-based gas may be used to etch the semiconductor layer 30 that uses a nitride semiconductor. Etching using a predetermined gas is performed using the metal layer 60 provided with the opening 60a as an etching mask. The etching stops at the position of the second portion 30b. By doing so, the via hole 61 that passes through the metal layer 60 and the substrate 20 to reach the second portion 30b without reaching the conductor layer 40 is formed.

After the via hole 61 depicted in FIG. 17A has been formed, the wiring 50 is formed in the via hole 61, thereby producing the state depicted in FIG. 16. That is, the seed layer 51 and the wiring layer 52 are sequentially formed using predetermined materials to form the wiring 50. The wiring 50 is formed to be connected to the second portion 30b at the bottom of the via hole 61. The wiring 50 may be formed on the metal layer 60 provided on the surface 20b-side of the substrate 20 in addition to the inner surface of the via hole 61.

Through the processes described above, the semiconductor device 10C with the configuration depicted in FIG. 16 is manufactured.

In the semiconductor device 10C depicted in FIG. 16, the conductor layer 40 is provided in the second portion 30b of the semiconductor layer 30 that has a larger surface area than the first portion 30a. Here, in the semiconductor device 10C, the wiring 50 does not pass through the second portion 30b and is electrically connected to the conductor layer 40 via the second portion 30b. This means that the contact area between the second portion 30b and the conductor layer 40 is larger than in a configuration where the wiring 50 passes through the second portion 30b. Accordingly, in the semiconductor device 10C, the adhesion of the conductor layer 40 to (the second portion 30b of) the semiconductor layer 30 is further improved. By doing so, peeling of the conductor layer 40 from the semiconductor layer 30 during manufacturing or operation of the semiconductor device 10C is more effectively suppressed, and poor conduction, such as disconnection, between the conductor layer 40 and the wiring 50 is more effectively suppressed. Accordingly, a high-quality and high-performance semiconductor device 10C, that is, a HEMT, is realized. The yield of the semiconductor device 10C is also improved.

Note that with the semiconductor device 10C, the second portion 30b may be regrown simultaneously with the third portions 30c formed as contact layers for the source electrode 82 and the drain electrode 83 in the same way as described in the third embodiment. In this case, processes are performed according to the example described with reference to FIGS. 14A to 14C and 15A while taking into account the thickness of the second portion 30b, the introduction of the n-type impurity, and the material of the conductor layer 40 as described earlier. After the state depicted in FIG. 15A has been obtained, the via hole 61 that reaches the second portion 30b but does not reach the conductor layer 40 is formed as depicted in FIG. 17B. After this, the wiring 50 is formed.

The semiconductor devices 1A to 1D, 10A to 10C, and the like described above may be applied to various electronic devices. As examples, configurations where the semiconductor devices 1A to 1D, 10A to 10C, and the like with the configurations described above are applied to a semiconductor package, a power factor correction circuit, a power supply device, and an amplifier are described below.

### Fifth Embodiment

Here, an example application of the semiconductor devices 1A to 1D, 10A to 10C, and the like with the configurations described above to a semiconductor package will be described as a fifth embodiment.

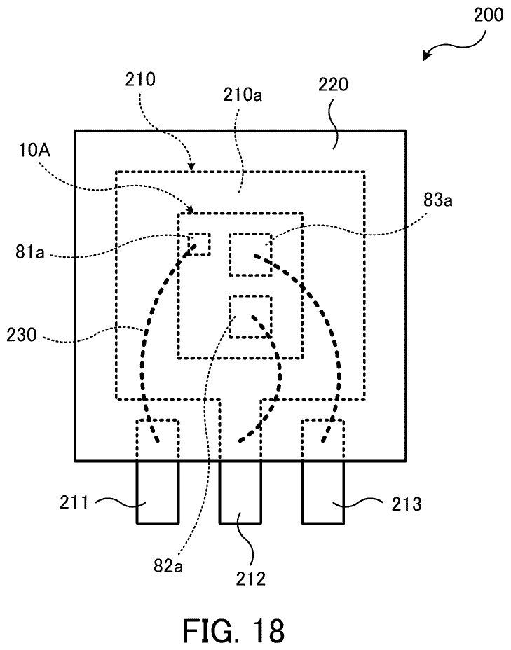

FIG. 18 is a diagram useful in describing one example of a semiconductor package according to a fifth embodiment. FIG. 18 is a schematic plan view of a principal part of one example of the semiconductor package.

The semiconductor package 200 depicted in FIG. 18 is one example of a discrete package. As one example, the semiconductor package 200 includes the semiconductor device 10A (see FIG. 8) described in the second embodiment, a lead frame 210 on which the semiconductor device 10A is mounted, and resin 220 that encapsulates the semiconductor device 10A and the lead frame 210.

As one example, the semiconductor device 10A is mounted on a die pad 210a of the lead frame 210 using a die attach material or the like (not illustrated). The semiconductor device 10A includes a pad 81a connected to the gate electrode 81 described above, a pad 82a connected to the source electrode 82, and a pad 83a connected to the drain electrode 83. The pad 81a, the pad 82a, and the pad 83a are respectively connected to a gate lead 211, a source lead 212, and a drain lead 213 of the lead frame 210 using wires 230 made of Au, Al, or the like. The lead frame 210, the semiconductor device 10A mounted on the lead frame 210, and the wires 230 connecting the lead frame 210 and the semiconductor device 10A are encapsulated with the resin 220 so that one part of each of the gate lead 211, the source lead 212, and the drain lead 213 is exposed.

An external connection electrode connected to the source electrode 82 may be provided on an opposite surface of the semiconductor device 10A to the surface on which the pad 81a connected to the gate electrode 81 and the pad 83a connected to the drain electrode 83 are provided. The external connection electrode may be connected to the die pad 210a connected to the source lead 212 using a conductive bonding material, such as solder.

As one example, the semiconductor device 10A described earlier in the second embodiment is used to obtain the semiconductor package 200 with the configuration described above. Although, the semiconductor device 10A is used here as an example, a semiconductor package may be obtained using the other semiconductor devices 1A to 1D, 10B, 10C, and the like.

As described above, in the semiconductor devices 1A to 1D, 10A to 10C, and the like, the conductor layer that functions as an etch stop layer when forming a via hole and functions as a part of the connecting conductor is provided on the semiconductor layer at a part of the semiconductor layer with a relatively large surface area. This means that adhesion of the conductor layer to the semiconductor layer is improved by an anchoring effect of the large-surface-area portion. By doing so, peeling of the conductor layer from the semiconductor layer and poor conduction, such as disconnection, between the conductor layer and the wiring are suppressed. Accordingly, high-quality and high-performance semiconductor devices 1A to 1D, 10A to 10C, and the like are realized. Such semiconductor devices 1A to 1D, 10A to 10C, and the like are used to realize a high-performance semiconductor package 200.

### Sixth Embodiment

Here, an example application of the semiconductor devices 1A to 1D, 10A to 10C, and the like with the configurations described above to a power factor improvement circuit will be described as a sixth embodiment.

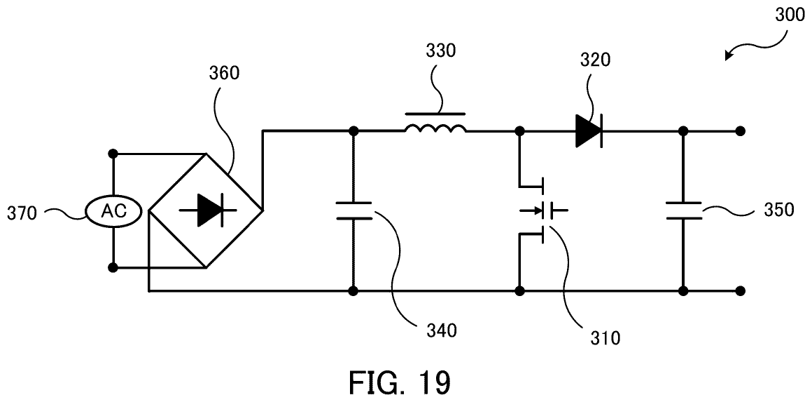

FIG. 19 is a diagram useful in describing one example of a power factor correction circuit according to a sixth embodiment. FIG. 19 is an equivalent circuit diagram of one example of a power factor correction circuit.

A power factor correction (PFC) circuit 300 depicted in FIG. 19 includes a switch element 310, a diode 320, a choke coil 330, a capacitor 340, a capacitor 350, a diode bridge 360, and an alternating current (AC) power supply 370.

In the PFC circuit 300, a drain electrode of the switch element 310 is connected to an anode terminal of the diode 320 and one terminal of the choke coil 330. A source electrode of the switch element 310 is connected to one terminal of the capacitor 340 and one terminal of the capacitor 350. The other terminal of the capacitor 340 and the other terminal of the choke coil 330 are connected to each other. The other terminal of the capacitor 350 and the cathode terminal of the diode 320 are connected to each other. A gate driver is connected to a gate electrode of the switch element 310. The AC power supply 370 is connected between both terminals of the capacitor 340 via the diode bridge 360, and direct current (DC) power is taken from both terminals of the capacitor 350.

As one example, the semiconductor devices 1A to 1D, 10A to 10C, and the like are used for the switch element 310 of the PFC circuit 300 with the configuration described above.

As described above, in the semiconductor devices 1A to 1D, 10A to 10C, and the like, the conductor layer that functions as an etch stop layer when forming the via hole and functions as a part of a connecting conductor is provided on the semiconductor layer in a part of the semiconductor layer with a relatively large surface area. This means that adhesion of the conductor layer to the semiconductor layer is improved by an anchoring effect achieved by the large-surface-area portion. By doing so, peeling of the conductor layer from the semiconductor layer and poor conduction, such as disconnection, between the conductor layer and the wiring are suppressed. Accordingly, high-quality and high-performance semiconductor devices 1A to 1D, 10A to 10C, and the like are realized. By using such semiconductor devices 1A to 1D, 10A to 10C, and the like, a high-performance PFC circuit 300 is realized.

### Seventh Embodiment

Here, an example application of the semiconductor devices 1A to 1D, 10A to 10C, and the like with the configurations described above to a power supply device will be described as a seventh embodiment.

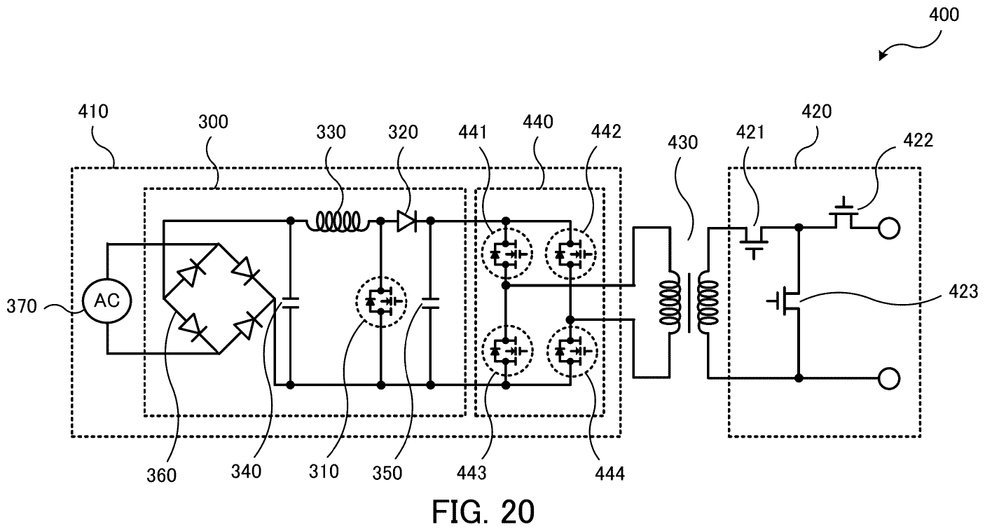

FIG. 20 is a diagram useful in describing one example of a power supply device according to a seventh embodiment. FIG. 20 is an equivalent circuit diagram of one example of a power supply device.

A power supply device 400 depicted in FIG. 20 includes a primary circuit 410, a secondary circuit 420, and a transformer 430 provided between the primary circuit 410 and the secondary circuit 420.

The primary circuit 410 includes the PFC circuit 300 as described in the sixth embodiment and an inverter circuit, for example, a full-bridge inverter circuit 440 connected between both terminals of the capacitor 350 of the PFC circuit 300. The full-bridge inverter circuit 440 includes a plurality of, as one example, four, switch elements 441, 442, 443, and 444.

The secondary circuit 420 includes a plurality of, for example, three, switch elements 421, 422, and 423.

As one example, in the power supply device 400 with the configuration described above, the semiconductor devices 1A to 1D, 10A to 10C, and the like are used for the switch element 310 of the PFC circuit 300 included in the primary circuit 410 and the switch elements 441 to 444 of the full-bridge inverter circuit 440. As one example, the semiconductor devices 1A to 1D, 10A to 10C, and the like described above are used for the switch elements 421, 422, and 423 of the secondary circuit 420 of the power supply device 400.

As described above, in the semiconductor devices 1A to 1D, 10A to 10C, and the like, the conductor layer that functions as an etch stop layer when forming the via hole and functions as a part of the connecting conductor is provided on the semiconductor layer in a part of the semiconductor layer with a relatively large surface area. This means that adhesion of the conductor layer to the semiconductor layer is improved by an anchoring effect achieved by the large-surface-area portion. By doing so, peeling of the conductor layer from the semiconductor layer and poor conduction, such as disconnection, between the conductor layer and the wiring are suppressed. Accordingly, high-quality and high-performance semiconductor devices 1A to 1D, 10A to 10C, and the like are realized. By using such semiconductor devices 1A to 1D, 10A to 10C, and the like, a high-performance power supply device 400 is realized.

### Eighth Embodiment

Here, an example application of the semiconductor devices 1A to 1D, 10A to 10C, and the like with the configurations described above to an amplifier will be described as an eighth embodiment.

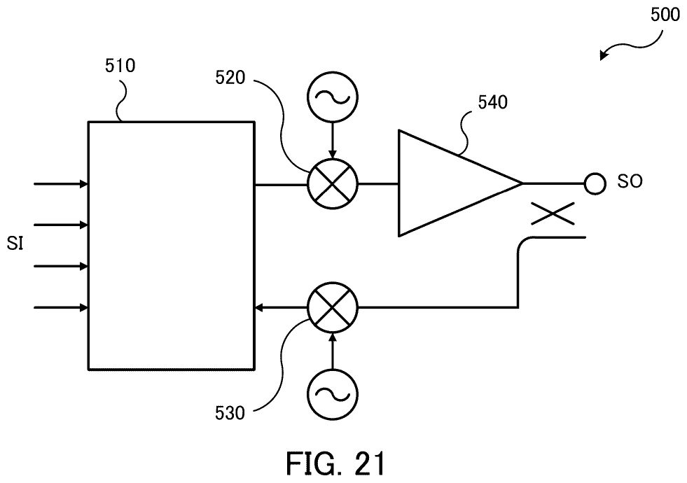

FIG. 21 is a diagram useful in describing one example of an amplifier according to an eighth embodiment. FIG. 21 is an equivalent circuit diagram of one example of an amplifier.

The amplifier 500 depicted in FIG. 21 includes a digital predistortion circuit 510, a mixer 520, a mixer 530, and a power amplifier 540.

The digital predistortion circuit 510 compensates for nonlinear distortion of an input signal. The mixer 520 mixes an input signal SI, whose nonlinear distortion has been compensated, with an AC signal. The power amplifier 540 amplifies a signal obtained by mixing the input signal SI with an AC signal. With the amplifier 500, as one example, it is possible, by switching switches, to mix an output signal SO with an AC signal using the mixer 530 and send the result to the digital predistortion circuit 510. The amplifier 500 may be used as a high-frequency amplifier or a high-power amplifier.

The semiconductor devices 1A to 1D, 10A to 10C, and the like are used for the power amplifier 540 of the amplifier 500 with the configuration described above.

As described above, in the semiconductor devices 1A to 1D, 10A to 10C, and the like, the conductor layer that functions as an etch stop layer when forming the via hole and functions as part of the connecting conductor is provided on the semiconductor layer in a part of the semiconductor layer with a relatively large surface area. This means that adhesion of the conductor layer to the semiconductor layer is improved by an anchoring effect achieved by the large-surface-area portion. By doing so, peeling of the conductor layer from the semiconductor layer and poor conduction, such as disconnection, between the conductor layer and the wiring are suppressed. Accordingly, high-quality and high-performance semiconductor devices 1A to 1D, 10A to 10C, and the like are realized. Such semiconductor devices 1A to 1D, 10A to 10C, and the like are used to realize a high-performance amplifier 500.

Various electronic devices (such as the semiconductor package 200, the PFC circuit 300, the power supply device 400, the amplifier 500, or the like described in the fifth to eighth embodiments) to which the semiconductor devices 1A to 1D, 10A to 10C, and the like described above have been applied may be installed in various electronic devices. As examples, installation in various electronic devices such as a computer (a personal computer, a supercomputer, a server, or the like), a smartphone, a mobile phone, a tablet terminal, a sensor, a camera, an audio device, a measurement device, an inspection device, a manufacturing device, a transmitter, a receiver, and a radar device is possible.

The disclosed techniques make it possible to achieve a high quality and high performance semiconductor device.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device comprising:
a substrate;
a semiconductor layer that is provided on a first surface side of the substrate and includes a first portion and a second portion, the second portion having a larger surface area than the first portion;
a conductor layer provided on an opposite side of the second portion to the substrate; and
wiring that passes through the substrate and is connected to the conductor layer.

2. The semiconductor device according to claim 1,
wherein the wiring passes through the substrate and the second portion and is connected to the conductor layer.

3. The semiconductor device according to claim 1,
wherein the second portion includes an n-type impurity.

4. The semiconductor device according to claim 3,
wherein the wiring passes through the substrate to reach the second portion and is connected to the conductor layer via the second portion.

5. The semiconductor device according to claim 1,
wherein the semiconductor layer includes:
a first semiconductor layer provided on the first surface side of the substrate; and
a second semiconductor layer provided on an opposite side of the first semiconductor layer to the substrate, the second semiconductor layer having a larger surface area than the first semiconductor layer,
wherein the first portion is provided on the first semiconductor layer, and
wherein the second portion is provided on the second semiconductor layer.

6. The semiconductor device according to claim 1, further comprising an electrode that is provided on an opposite side of the first portion to the substrate and is connected to the conductor layer.

7. The semiconductor device according to claim 1,
wherein the semiconductor layer further includes a third portion that has a larger surface area than the first portion,
wherein the third portion contains an n-type impurity, and
wherein the semiconductor device further includes an electrode provided on an opposite side of the third portion to the substrate and is connected to the conductor layer.

8. A method of manufacturing a semiconductor device, comprising:
forming a semiconductor layer on a first surface side of a substrate, the semiconductor layer including a first portion and a second portion that has a larger surface area than the first portion;
forming a conductor layer on an opposite side of the second portion to the substrate; and
forming wiring that passes through the substrate and is connected to the conductor layer.

9. The method of manufacturing a semiconductor device according to claim 8,
wherein the forming of the wiring includes forming the wiring so as to pass through the substrate and the second portion and connect to the conductor layer.

10. The method of manufacturing a semiconductor device according to claim 8,
wherein the second portion includes an n-type impurity.

11. The method of manufacturing a semiconductor device according to claim 10,
wherein the forming of the wiring includes forming the wiring so as to pass through the substrate, reach the second portion, and connect to the conductor layer via the second portion.

12. The method of manufacturing a semiconductor device according to claim 8,
wherein the forming of the semiconductor layer includes:
forming a first semiconductor layer on the first surface side of the substrate; and
forming a second semiconductor layer with a larger surface area than the first semiconductor layer on an opposite side of the first semiconductor layer to the substrate,
wherein the first portion is provided on the first semiconductor layer, and
wherein the second portion is provided on the second semiconductor layer.

13. The method of manufacturing a semiconductor device according to claim 8, further comprising forming an electrode connected to the conductor layer on an opposite side of the first portion to the substrate.

14. The method of manufacturing a semiconductor device according to claim 8,
wherein the semiconductor layer further includes a third portion with a larger surface area than the first portion,
wherein the third portion includes an n-type impurity, and
wherein the method further includes forming an electrode connected to the conductor layer on an opposite side of the third portion to the substrate.

15. An electronic device comprising:
a substrate;
a semiconductor layer that is provided on a first surface side of the substrate and includes a first portion and a second portion, the second portion having a larger surface area than the first portion;
a conductor layer provided on an opposite side of the second portion to the substrate; and
wiring that passes through the substrate and is connected to the conductor layer.
